(19) United States
(12) Patent Application Publication
(10) Pub. No.: US 2026/0313906 A1
(43) Pub. Date: Oct. 8, 2026

(54) SEMICONDUCTOR DEVICE INCLUDING FERROELECTRIC MATERIAL FILM AND METHOD FOR FABRICATING A SEMICONDUCTOR DEVICE

(71) Applicant: SAMSUNG ELECTRONICS CO., LTD., Suwon-si (KR)

(72) Inventor: Ji Hye SUH, Suwon-si (KR)

(73) Assignee: SAMSUNG ELECTRONICS CO., LTD., Suwon-si (KR)

(21) Appl. No.: 19/424,974

(22) Filed: Dec. 18, 2025

(30) Foreign Application Priority Data
Apr. 2, 2025 (KR) 10-2025-0042867

(51) Int. Cl. H10B 51/30; G11C 5/06; H10B 12/00; H10B 51/20; H10B 51/40; H10D 30/01; H10D 30/69; H10D 62/17; H10D 62/83; H10W 80/00

(52) U.S. Cl. CPC H10B 51/30; G11C 5/063; H10B 12/00; H10B 51/20; H10D 30/701; H10D 62/292; H10D 62/83; H10B 12/01; H10B 51/40; H10D 30/0415; H10W 80/312

(57) ABSTRACT

A semiconductor device includes a first bit line extending in a first direction, a first channel pattern on the first bit line, and connected to the first bit line, a first word line on the first channel pattern, and extending in a second direction, a lower gate insulating pattern between the first channel pattern and the first word line, a second bit line extending in the second direction, and spaced apart from the first word line in a third direction, a second channel pattern on the second bit line, and contacting the second bit line, an upper gate insulating pattern between the first channel pattern and the second channel pattern, between the first channel pattern and the second bit line, contacting the first channel pattern, and including a ferroelectric material film, and a second word line on the second channel pattern, and extending in the first direction.

### CROSS-REFERENCE TO RELATED APPLICATION

This application claims priority under 35 U.S.C. § 119 to Korean Patent Application No. 10-2025-0042867, filed on Apr. 2, 2025, in the Korean Intellectual Property Office, the disclosure of which is incorporated by reference herein in its entirety.

### BACKGROUND

### 1. Field

The present disclosure relates to a semiconductor device and a method for fabricating a semiconductor device, and more particularly, to a semiconductor device including a vertical channel transistor (VCT) and a method for fabricating a semiconductor device including a VCT.

### 2. Description of Related Art

There is a need to increase the degree of integration of a semiconductor device to satisfy excellent performance and low price required by consumers. In the case of the semiconductor device, because the degree of integration is an important factor in determining the price of a product, an increased degree of integration is particularly required.

In the case of a two-dimensional or planar semiconductor device, the degree of integration is mainly determined by an area occupied by unit memory cells, and is therefore greatly affected by the level of fine pattern forming technology. However, because ultra-expensive apparatuses are required to miniaturize the pattern, the degree of integration of the two-dimensional semiconductor device is increasing, but is still limited. Accordingly, semiconductor devices including a vertical channel transistor with a channel extending in a vertical direction have been proposed.

### SUMMARY

One or more example embodiments of the present disclosure provide a semiconductor device which may have an improved degree of integration and improved electrical characteristics.

Further, one or more example embodiments provide a method for fabricating a semiconductor device which may have an improved degree of integration and improved electrical characteristics.

According to an aspect of the disclosure, a semiconductor device includes: a first bit line extending in a first direction, and including a first side and a second side opposite to the first side; a first channel pattern on the first side of the first bit line, and connected to the first bit line; a first word line on the first channel pattern, and extending in a second direction; a lower gate insulating pattern between the first channel pattern and the first word line; a second bit line extending in the second direction, and spaced apart from the first word line in a third direction; a second channel pattern on the second bit line, and in contact with the second bit line; an upper gate insulating pattern between the first channel pattern and the second channel pattern, between the first channel pattern and the second bit line, and in contact with the first channel pattern, the upper gate insulating pattern including a ferroelectric material film; and a second word line on the second channel pattern, and extending in the first direction.

According to an aspect of the disclosure, a semiconductor device includes: a first bit line extending in a first direction, and including a first side and a second side opposite to the first side; a first channel pattern on the first side of the first bit line, and which is connected to the first bit line; a first word line on the first channel pattern, and extending in a second direction; a lower gate insulating pattern between the first channel pattern and the first word line; an upper gate insulating pattern on the first word line and the lower gate insulating pattern, and including a ferroelectric material film; a second bit line on the upper gate insulating pattern, and extending in the second direction; a second channel pattern on the second bit line, and in contact with the second bit line; and a second word line on the second channel pattern, and extending in the first direction, wherein the upper gate insulating pattern includes a horizontal portion extending in the first direction, and vertical portions extending in a third direction, and wherein the horizontal portion of the upper gate insulating pattern is between the first word line and the second bit line.

According to an aspect of the disclosure, a semiconductor device includes: a first bit line extending in a first direction, and including a first side and a second side opposite to the first side; a protruding insulating pattern on the first side of the first bit line, and including a channel trench extending in a second direction; a first channel pattern extending along side walls and a bottom side of the channel trench, and is connected to the first bit line; a first lower word line on the first channel pattern and extending in the second direction; a second lower word line on the first channel pattern, extending in the second direction, and spaced apart from the first lower word line in the first direction; a lower gate insulating pattern between the first channel pattern and the first lower word line, and between the first channel pattern and the second lower word line; an upper gate insulating pattern on the first channel pattern, the first lower word line, and the second lower word line, and in contact with the first channel pattern, the upper gate insulating pattern including a horizontal portion extending in the first direction, and vertical portions extending in a third direction; a first upper bit line on the upper gate insulating pattern, and extending in the second direction; a second upper bit line extending in the second direction, and spaced apart from the first upper bit line in the first direction; a second channel pattern on the first upper bit line and the second upper bit line, and in contact with the first upper bit line and the second upper bit line; and a second word line on an upper side of the protruding insulating pattern, and extending in the first direction, wherein the upper gate insulating pattern includes a ferroelectric material film.

### BRIEF DESCRIPTION OF DRAWINGS

The above and other aspects and features will be more apparent from the following detailed description of embodiments taken in conjunction with the attached drawings, in which:

FIG. 1 is a circuit diagram of a semiconductor device according to one or more example embodiments.

FIG. 2 is a perspective view of the semiconductor device according to one or more example embodiments.

FIG. 3 is a plan view of the semiconductor device according to one or more example embodiments.

FIGS. 4, 5 and 6 are cross-sectional views taken along lines A-A, B-B, and C-C of FIG. 3, according to one or more example embodiments.

FIG. 7 is an enlarged view of a portion P of FIG. 4, according to one or more example embodiments.

FIGS. 8, 9 and 10 are enlarged views of a portion Q of FIG. 4, according to one or more example embodiments.

FIGS. 11 and 12 are diagrams for explaining a semiconductor device according to one or more example embodiments.

FIGS. 13 and 14 are diagrams for explaining the semiconductor device according to one or more example embodiments.

FIGS. 15 and 16 are diagrams for explaining semiconductor devices according to one or more example embodiments.

FIG. 17 is a diagram for explaining a semiconductor device according to one or more example embodiments.

FIG. 18 is a diagram for explaining a semiconductor memory device according to one or more example embodiments.

FIGS. 19, 20, 21, 22, 23, 24, 25, 26, 27, 28, 29, 30, 31, 32, 33, 34, 35, 36, 37, 38, 39, 40 and 41 are intermediate stage diagrams for explaining a semiconductor device according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of one or more example embodiments.

As used herein, expressions such as “at least one of,” when preceding a list of elements, modify the entire list of elements and do not modify the individual elements of the list. For example, the expression, “at least one of a, b, or c,” should be understood as including only a, only b, only c, both a and b, both a and c, both b and c, or all of a, b, and c.

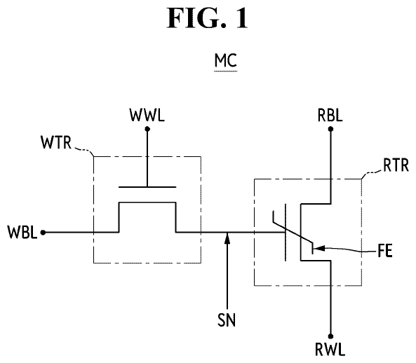

FIG. 1 is a circuit diagram of a semiconductor device according to one or more example embodiments.

Referring to FIG. 1, a memory cell MC may include a write transistor WTR, and a read transistor RTR connected to the write transistor WTR. The semiconductor device according to one or more example embodiments may include a plurality of memory cells arranged two-dimensionally or three-dimensionally.

The write transistor WTR may include a write word line WWL connected to a gate terminal of the write transistor WTR, and a write bit line WBL connected to a source terminal of the write transistor WTR. The read transistor RTR may include a read word line RWL and a read bit line RBL that are each connected to source/drain terminals of the read transistor RTR.

A drain terminal of the write transistor WTR may be connected to the gate terminal of the read transistor RTR. In addition, a ferroelectric material film FE may be connected to the gate terminal of the read transistor RTR. The drain terminal of the write transistor WTR may be connected to the ferroelectric material film FE connected to the gate terminal of the read transistor RTR.

The drain terminal of the write transistor WTR may be called a storage node SN. The storage node SN may serve to store charges. The storage node SN may be connected to the ferroelectric material film FE, and may polarize the ferroelectric material film FE. The charges stored in the storage node SN may induce polarization of the ferroelectric material film FE. The charges stored in the storage node SN may switch a polarization direction of the ferroelectric material film FE. In addition, the degree of polarization of the ferroelectric material film FE may vary depending on the amount of charges stored in the storage node SN. A threshold voltage of the read transistor RTR may change depending on the polarization direction and/or degree of polarization of the ferroelectric material film FE. The ferroelectric material film FE connected to the gate terminal of the read transistor RTR may function as a gate insulating film of the read transistor RTR.

As an example, a program operation of the memory cell MC may be as follows: A voltage is applied to the write word line WWL and the write bit line WBL, and the write transistor WTR may be turned on. As the write transistor WTR is turned on, an electric signal (charges) may be transferred (charged) to the storage node SN. Accordingly, the electric signal of the write bit line WBL may be stored in the storage node SN. The charges stored in the storage node SN may polarize the ferroelectric material film FE. As a result, the threshold voltage of the read transistor RTR may change.

In the program operation of the memory cell MC, the amount of charges stored in the storage node SN may change depending on the magnitude of the voltage applied to the write bit line WBL. In other words, the degree of polarization of the ferroelectric material film FE may change depending on the magnitude of the voltage applied to the write bit line WBL.

As an example, a read operation of the memory cell MC may be as follows: The write transistor WTR is turned off, the read bit line RBL is held at 0 V, and a read voltage V_{read} may be applied to the read word line RWL. The polarization direction and/or degree of polarization of the ferroelectric material film FE may be read through the current flowing through the read transistor RTR. In other words, the magnitude of the current flowing through a channel region of the read transistor RTR may change depending on the polarization direction and/or degree of polarization of the ferroelectric material film FE.

Because the magnitude of the voltage applied to the write bit line WBL is adjusted during the write operation, the degree of polarization of the ferroelectric material film FE may change to several levels. The threshold voltage of the read transistor RTR may change to several levels depending on the degree of polarization of the ferroelectric material film FE. As a result, a multi-bit memory cell MC may be implemented.

The semiconductor device including the memory cell MC may also be called a two-transistor zero-capacitor (2T-0C) memory element. The semiconductor device according to one or more example embodiments may not include a separate capacitor for storing the charges. Therefore, because an area required to form the capacitor may decrease, the high integration of the semiconductor device is enabled.

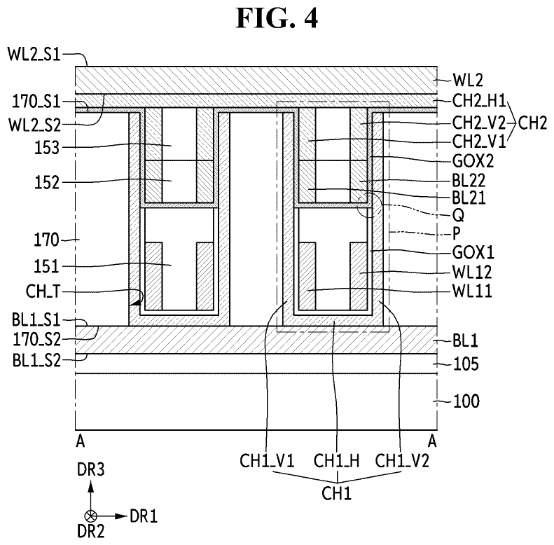

The semiconductor device including the 2T-0C memory element according to one or more example embodiments may include a vertical channel transistor (VCT). The vertical channel transistor refers to a structure in which the channel of the transistor extends in a direction perpendicular to an upper side of the substrate 100 (a third direction DR3 of FIG. 4).

When the storage node SN functions as the gate of the read transistor RTR, the threshold voltage of the read transistor RTR may change depending on the amount of charges stored in the storage node SN. As an example, the amount of charges stored in the storage node SN may decrease due to a leakage current of the write transistor WTR. As another example, during the write operation of the memory cell MC, the amount of charges stored in the storage node SN may decrease due to capacitive coupling between the write word line WWL and the storage node SN. As another example, during the read operation of the memory cell MC, the amount of charges stored in the storage node SN may decrease due to the capacitive coupling between the read word line RWL and the storage node SN.

When the amount of charges stored in the storage node SN decreases, a retention time and a read current of the memory cell MC may decrease. Furthermore, the sensing margin may decrease during the read operation of the memory cell MC. This may result in a decrease in the performance and reliability of the semiconductor device.

Hereinafter, a case where the ferroelectric material film FE functions as the gate of the read transistor RTR will be described. Even if the leakage current of the write transistor WTR occurs, the polarization direction and/or degree of the ferroelectric material film FE may not change. In addition, even if a capacitive coupling occurs between the write word line WWL and the storage node SN during the write operation of the memory cell MC, the polarization direction and/or degree of the ferroelectric material film FE may not change. In addition, even if a capacitive coupling occurs between the read word line RWL and the storage node SN during the read operation of the memory cell MC, the polarization direction and/or degree of the ferroelectric material film FE may not change. In other words, because the ferroelectric material film FE functions as the gate of the read transistor RTR, the retention time of the memory cell MC may be improved. The read current of the memory cell MC may not also decrease, but a sensing margin does not decrease during the read operation of the memory cell MC. Accordingly, the performance and reliability of the semiconductor device including the 2T-0C memory element may be improved.

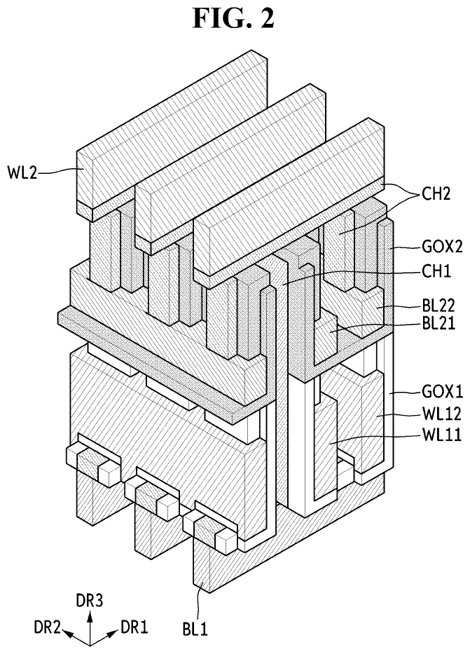

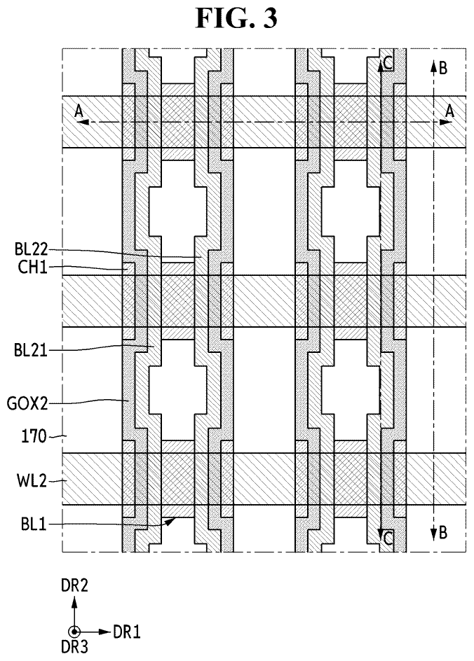

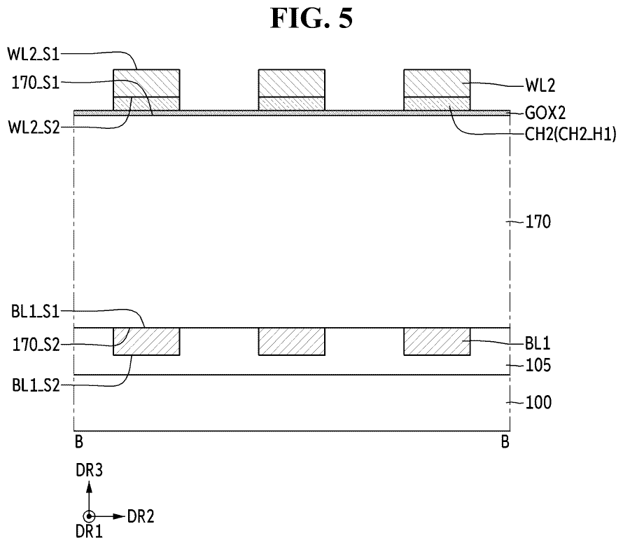

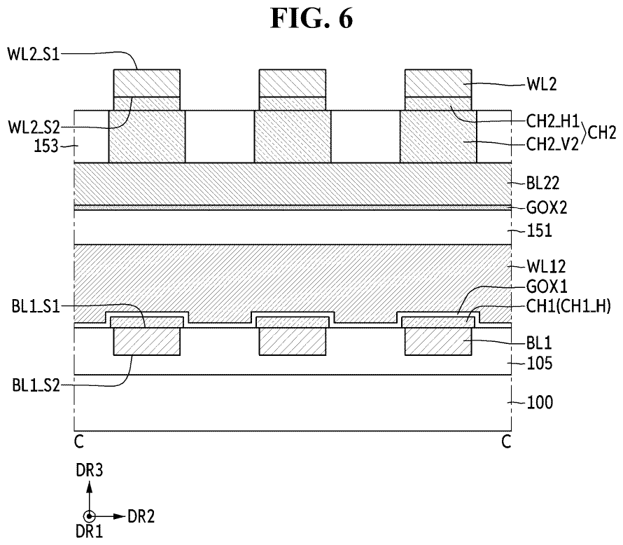

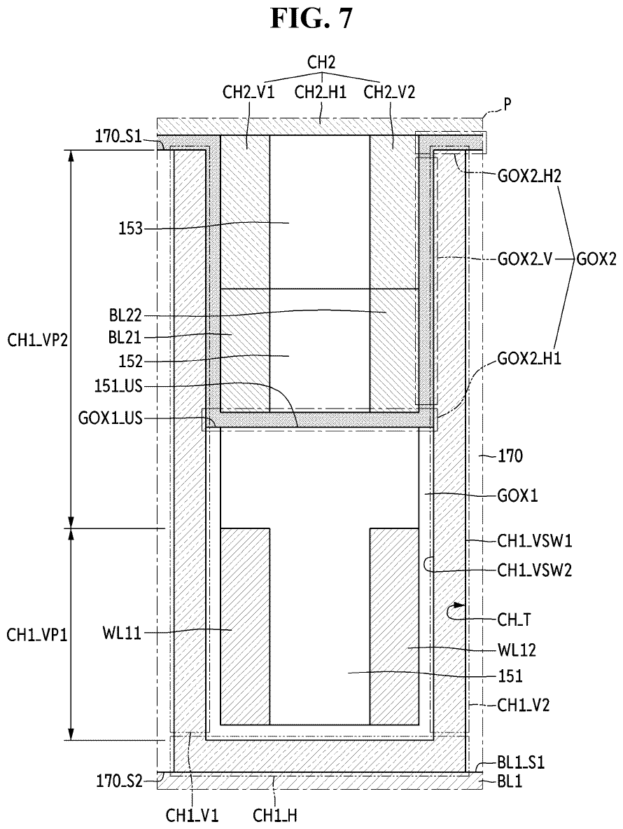

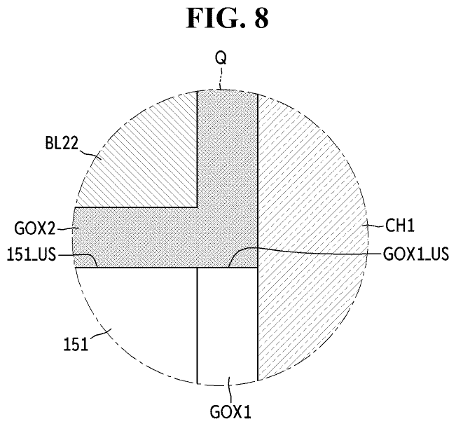

FIG. 2 is a perspective view of the semiconductor device according to one or more example embodiments. FIG. 3 is a plan view of the semiconductor device according to one or more example embodiments. FIGS. 4, 5 and 6 are cross-sectional views taken along lines A-A, B-B, and C-C of FIG. 3. FIG. 7 is an enlarged view of a portion P of FIG. 4. FIGS. 8, 9 and 10 are enlarged views of a portion Q of FIG. 4.

For reference, a second channel pattern CH2 is not shown in FIG. 3.

Referring to FIGS. 2, 3, 4, 5, 6, 7, 8, 9 and 10, the semiconductor device according to one or more example embodiments may include a first bit line BL1, first word lines WL11 and WL12, second bit lines BL21 and BL22, a second word line WL2, a first channel pattern CH1, a second channel pattern CH2, a first lower gate insulating pattern GOX1, and a first upper gate insulating pattern GOX2.

As an example, the substrate 100 may be a silicon substrate, or may include other materials, for example, silicon germanium, indium antimonide, lead telluride, indium arsenide, indium phosphide, gallium arsenide, or gallium antimonide. As another example, the substrate 100 may include a ceramic substrate, a quartz substrate or a glass substrate. As still another example, the substrate 100 may include a flexible plastic substrate, such as polyimide, polyethylene terephthalate (PET), polyethylene naphthalate (PEN), poly methyl methacrylate (PMMA), polycarbontate (PC), polyethersulfone PES or polyester.

The lower insulating film 105 may be disposed on the substrate 100. The lower insulating film 105 may be made of an insulating material. Unlike the example embodiment shown in FIG. 4, the lower insulating film 105 may not be disposed on the substrate 100.

The first bit line BL1 may be disposed on the substrate 100. The first bit line BL1 may be disposed on the lower insulating film 105.

Each of a plurality of first bit lines BL1 may extend in a first direction DR1. The plurality of first bit lines BL1 may be adjacent to each other in a second direction DR2.

The first bit line BL1 may include a first side BL1_S1 and a second side BL1_S2 that are opposite to each other in the third direction DR3. The second side BL1_S2 of the first bit line may face the substrate 100.

According to one or more example embodiments, the first direction DR1 and the second direction DR2 may be orthogonal to a third direction DR3. The first direction DR1 may intersect the second direction DR2. For example, the third direction DR3 may be a thickness direction of the substrate 100. The first direction DR1 and the second direction DR2 may be parallel to the upper side of the substrate 100.

For example, the first bit line BL1 may correspond to the write bit line WBL of the write transistor WTR of FIG. 1.

The first bit line BL1 may include a conductive material. The first bit line BL1 may include, for example, at least one of a doped semiconductor material, a conductive metal nitride, a conductive metal silicon nitride, a conductive metal carbonitride, a conductive metal silicide, a conductive metal oxide, a two-dimensional material or a metal. The first bit line BL1 is shown as being a single film according to one or more example embodiments, but is not limited thereto.

In the semiconductor device according to one or more example embodiments, the two-dimensional material may be a metallic material and/or a semiconductor material. The two-dimensional material (2D material) may include a 2D allotrope or a 2D compound, and may include, for example, but is not limited to, at least one of graphene, molybdenum disulfide (MoS₂), molybdenum diselenide (MoSe₂), tungsten diselenide (WSe₂), and tungsten disulfide (WS₂). That is, because the above-mentioned 2D materials are only listed as examples, the 2D materials that may be included in the semiconductor device of one or more example embodiments are not limited by the above-mentioned example materials.

A first protruding insulating pattern 170 may be disposed on the first bit line BL1. The first protruding insulating pattern 170 may be disposed on the first side BL1_S1 of the first bit line BL1. The first protruding insulating pattern 170 may include an insulating material.

The first protruding insulating pattern 170 may include a first side 170_S1 and a second side 170_S2 that are opposite to each other in the third direction DR3. The second side 170_S2 of the first protruding insulating pattern 170 may face the first bit line BL1. For example, the first side 170_S1 of the first protruding insulating pattern 170 may be an upper side of the first protruding insulating pattern 170. The second side 170_S2 of the first protruding insulating pattern 170 may be a bottom side of the first protruding insulating pattern 170.

Unlike the one or more example embodiments shown in FIG. 4, an etching stop film extending along the second side 170_S2 of the first protruding insulating pattern 170 may be further disposed between the first protruding insulating pattern 170 and the substrate 100.

The first protruding insulating pattern 170 may include a plurality of first channel trenches CH_T. Each of the first channel trenches CH_T may extend in the second direction DR2. Adjacent first channel trenches CH_T may be spaced apart in the first direction DR1.

Each of the first channel trenches CH_T may intersect the first bit line BL1. One of the first channel trenches CH_T may expose a plurality of first bit lines BL1 adjacent to each other in the second direction DR2. The one of the first channel trenches CH_T may expose the first side BL1_S1 of the first bit line.

The bottom side of each of the first channel trenches CH_T may be defined by the first bit line BL1 and the lower insulating film 105. The side walls of each of the first channel trenches CH_T may be defined by the first protruding insulating pattern 170.

The first channel pattern CH1 may be disposed on each first bit line BL1. For example, the first channel pattern CH1 may be disposed on the first side BL1_S1 of each first bit line BL1. A plurality of first channel patterns CH1 may be connected to one first bit line BL1. The plurality of first channel patterns CH1 disposed on one first bit line BL1 may be spaced apart in the first direction DR1.

The first channel pattern CH1 may be disposed inside one of the first channel trenches CH_T extending in the second direction DR2. A plurality of first channel patterns CH1 may be disposed inside one of the first channel trenches CH_T. The plurality of first channel patterns CH1 disposed inside the one of the first channel trenches CH_T may be spaced apart in the second direction DR2. For example, the first channel patterns CH1 may be disposed two-dimensionally along the first direction DR1 and the second direction DR2 that intersect each other.

The first channel pattern CH1 may extend along the side wall and bottom side of the first channel trench CH_T. For example, the first channel pattern CH1 may be in contact with the first protruding insulating pattern 170. In the semiconductor device according to one or more example embodiments, the first channel pattern CH1 may have a “U” shape in a cross section that is taken along the first direction DR1.

The first channel pattern CH1 may include a horizontal portion CH1_H and a plurality of vertical portions CH1_V1 and CH1_V2. The vertical portions CH1_V1 and CH1_V2 of the first channel pattern CH1 may include a first vertical portion CH1_V1 and a second vertical portion CH1_V2 that are spaced apart in the first direction DR1.

The horizontal portion CH1_H of the first channel pattern CH1 may extend along the bottom side of the first channel trench CH_T. From the viewpoint of the cross-sectional view such as FIG. 4, the horizontal portion CH1_H of the first channel pattern CH1 may extend in the first direction DR1. The horizontal portion CH1_H of the first channel pattern CH1 may be connected to the first side BL1_S1 of the first bit line BL1.

The first vertical portion CH1_V1 of the first channel pattern CH1 and the second vertical portion CH1_V2 of the first channel pattern CH1 may be disposed on the side wall of the first channel trench CH_T. The first vertical portion CH1_V1 of the first channel pattern CH1 and the second vertical portion CH1_V2 of the first channel pattern CH1 may extend along the side wall of the first channel trench CH_T. The first vertical portion CH1_V1 of the first channel pattern CH1 and the second vertical portion CH1_V2 of the first channel pattern CH1 may each protrude from the horizontal portion CH1_H of the first channel pattern CH1 in the third direction DR3. The first vertical portion CH1_V1 of the first channel pattern CH1 and the second vertical portion CH1_V2 of the first channel pattern CH1 may each extend in the third direction DR3. The first vertical portion CH1_V1 of the first channel pattern CH1 and the second vertical portion CH1_V2 of the first channel pattern CH1 may extend up to the first side 170_S1 of the first protruding insulating pattern 170.

The vertical portions CH1_V1 and CH1_V2 of the first channel pattern CH1 may include a first side wall CH1_VSW1 and a second side wall CH1_VSW2 that are opposite to each other in the first direction DR1. The first side wall CH1_VSW1 of the first vertical portion CH1_V1 of the first channel pattern CH1 and the first side wall CH1_VSW1 of the second vertical portion CH1_V2 of the first channel pattern CH1 may face the first protruding insulating pattern 170. The second side wall CH1_VSW2 of the first vertical portion CH1_V1 of the first channel pattern CH1 may face the second side wall CH1_VSW2 of the second vertical portion CH1_V2 of the first channel pattern CH1.

The vertical portions CH1_V1 and CH1_V2 of the first channel pattern CH1 may include a first region CH1_VP1 and a second region CH1_VP2. The second region CH1_VP2 of the vertical portion of the first channel pattern CH1 may be disposed on the first region CH1_VP1 of the vertical portion of the first channel pattern CH1. The first region CH1_VP1 of the vertical portion of the first channel pattern CH1 may be disposed between the horizontal portion CH1_H of the first channel pattern CH1 and the second region CH1_VP2 of the vertical portion of the first channel pattern CH1. The first region CH1_VP1 of the vertical portion of the first channel pattern CH1 may be directly connected to the horizontal portion CH1_H of the first channel pattern CH1.

The first region CH1_VP1 of the vertical portion of the first channel pattern CH1 may overlap the first word lines WL11 and WL12 in the first direction DR1, and may not overlap the second bit lines BL21 and BL22 in the first direction DR1. The second region CH1_VP2 of the vertical portion of the first channel pattern CH1 may overlap the second bit lines BL21 and BL22 in the first direction DR1, and may not overlap the first word lines WL11 and WL12 in the first direction DR1. Although FIG. 7 shows that, according to one or more example embodiments, the first region CH1_VP1 of the vertical portion of the first channel pattern CH1 and the second region CH1_VP2 of the vertical portion of the first channel pattern CH1 are divided in the lower portion of the first upper gate insulating pattern GOX2, this is only for convenience of explanation, and one or more example embodiments are not limited thereto.

For example, the first region CH1_VP1 of the vertical portion of the first channel pattern CH1 may be used as the channel region of the write transistor WTR of one or more example embodiments shown in FIG. 1. The second region CH1_VP2 of the vertical portion of the first channel pattern CH1 may be a portion corresponding to the storage node SN of one or more example embodiments shown in FIG. 1.

As an example, the first channel pattern CH1 may include an oxide semiconductor material. The first channel pattern CH1 may include, for example, a metal oxide. As an example, the first channel pattern CH1 may be an amorphous metal oxide film. As another example, the first channel pattern CH1 may be a polycrystalline metal oxide film. As yet another example, the first channel pattern CH1 may be a combination of the amorphous metal oxide film and the polycrystalline metal oxide film. As yet another example, the first channel pattern CH1 may be a c-axis aligned crystalline (CAAC) metal oxide film.

The first channel pattern CH1 may include, for example, but is not limited to, at least one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and In—Hf—Al—Zn-based oxide.

According to one or more example embodiments, the In—Ga—Zn-based oxide means an oxide that has In, Ga, and Zn as main components, but does not mean a ratio of In, Ga, and Zn. That is, taking indium gallium zinc oxide (IGZO) as an example, the first channel pattern CH1 may include IGZO (InₓGa_{y}Zn_{z}O). The IGZO (In:Ga:Zn=1:1:1) containing indium, gallium and zinc at the same ratio may be an In—Ga—Zn-based oxide. A Ga-rich IGZO may have a higher ratio of gallium than the IGZO (In:Ga:Zn=1:1:1), and a lower ratio of indium than the IGZO (In:Ga:Zn=1:1:1). The Ga-rich IGZO may also be an In—Ga—Zn-based oxide. An In-rich IGZO may also have a higher ratio of indium than IGZO (In:Ga:Zn=1:1:1) and a lower ratio of gallium than IGZO (In:Ga:Zn=1:1:1). The In-rich IGZO may also be an In—Ga—Zn-based oxide.

Although the above description has been made using IGZO, one or more example embodiments are not limited thereto. Needless to say, the above description may be applied when the first channel pattern CH1 includes a ternary or more metal oxide. Also, the first channel pattern CH1 may further include a doped metal element other than In, Ga, and Zn, when the first channel pattern CH1 includes the In—Ga—Zn-based oxide.

In the semiconductor device according to one or more example embodiments, the horizontal portion CH1_H of the first channel pattern CH1 and the first region CH1_VP1 of the vertical portion of the first channel pattern CH1 may have crystallinity, and the second region CH1_VP2 of the vertical portion of the first channel pattern CH1 may be amorphous.

In the semiconductor device according to one or more example embodiments, the horizontal portion CH1_H of the first channel pattern CH1 and the first region CH1_VP1 of the vertical portion of the first channel pattern CH1 may have a relatively high oxygen concentration compared to the second region CH1_VP2 of the vertical portion of the first channel pattern CH1. Accordingly, the second region CH1_VP2 of the vertical portion of the first channel pattern CH1 may have relative metallicity compared to the first region CH1_VP1 of the vertical portion of the first channel pattern CH1.

As another example, the first channel pattern CH1 may include a two-dimensional semiconductor material.

The first word lines WL11 and WL12 may be disposed on the first channel pattern CH1. The first word lines WL11 and WL12 may be disposed inside the first channel trench CH_T.

The first word lines WL11 and WL12 may be disposed on the horizontal portion CH1_H of the first channel pattern CH1. The first word lines WL11 and WL12 may be disposed between the first vertical portion CH1_V1 of the first channel pattern CH1 and the second vertical portion CH1_V2 of the first channel pattern.

The first word lines WL11 and WL12 may include a first lower word line WL11 and a second lower word line WL12. Each of the first lower word line WL11 and the second lower word line WL12 may extend in the second direction DR2. The first lower word line WL11 and the second lower word line WL12 may be arranged alternately in the first direction DR1. The first lower word line WL11 and the second lower word line WL12 may be spaced apart in the first direction DR1.

The first vertical portion CH1_V1 of the first channel pattern CH1 may be disposed closer to the first lower word line WL11 than to the second lower word line WL12. The first lower word line WL11 may be disposed on the second side wall CH1_VSW2 of the first vertical portion CH1_V1 of the first channel pattern CH1. The second vertical portion CH1_V2 of the first channel pattern CH1 may be disposed closer to the second lower word line WL12 than to the first lower word line WL11. The second lower word line WL12 may be disposed on the second side wall CH1_VSW2 of the second vertical portion CH1_V2 of the first channel pattern CH1.

The first lower word line WL11 may not be disposed on the first side wall CH1_VSW1 of the first vertical portion CH1_V1 of the first channel pattern CH1. The second lower word line WL12 may not be disposed on the first side wall CH1_VSW1 of the second vertical portion CH1_V2 of the first channel pattern CH1.

For example, each of the first lower word line WL11 and the second lower word line WL12 may correspond to the write word line WWL of the write transistor WTR of one or more example embodiments shown in FIG. 1.

The first word lines WL11 and WL12 may include a conductive material. The first word lines WL11 and WL12 may include at least one of, for example, a doped semiconductor material, a conductive metal nitride, a conductive metal silicon nitride, a conductive metal carbonitride, a conductive metal silicide, a conductive metal oxide, a two-dimensional material or a metal. Although the first word lines WL11 and WL12 are shown as being a single film, one or more example embodiments are not limited thereto.

The first lower gate insulating pattern GOX1 may extend along a part of the profile of the first channel pattern CH1. For example, the first lower gate insulating pattern GOX1 may extend along the second side wall CH1_VSW2 of the first vertical portion CH1_V1 of the first channel pattern CH1 and the second side wall CH1_VSW2 of the second vertical portion CH1_V2 of the first channel pattern CH1.

The first lower gate insulating pattern GOX1 may not extend up to the first side 170_S1 of the first protruding insulating pattern 170. On the basis of the first side BL1_S1 of the first bit line, the uppermost side GOX1_US of the first lower gate insulating pattern GOX1 may be lower than the first side 170_S1 of the first protruding insulating pattern 170.

The first lower gate insulating pattern GOX1 may be disposed between the first channel pattern CH1 and the first lower word line WL11, and between the first channel pattern CH1 and the second lower word line WL12. The first channel pattern CH1 and the first lower gate insulating pattern GOX1 of the first lower word line WL11 may be connected to the first lower gate insulating pattern GOX1 between the first channel pattern CH1 and the second lower word line WL12.

The first lower gate insulating pattern GOX1 may include a silicon oxide film, a silicon oxynitride film, a high dielectric constant insulating film having a higher dielectric constant than the silicon oxide film, or a combination thereof. The high dielectric constant insulating film may include a metal oxide or a metal oxynitride. For example, the first lower gate insulating pattern GOX1 may include, but is not limited to, aluminum oxide.

A first isolation insulating pattern 151 may be disposed on the first lower gate insulating pattern GOX1. The first isolation insulating pattern 151 may be disposed inside the first channel trench CH_T.

The first isolation insulating pattern 151 may be disposed between the first lower word line WL11 and the second lower word line WL12 that are adjacent to each other in the first direction DR1. The first isolation insulating pattern 151 may cover an upper side of the first lower word line WL11 and an upper side of the second lower word line WL12. The first isolation insulating pattern 151 may not be in contact with the horizontal portion CH1_H of the first channel pattern CH1. The first isolation insulating pattern 151 includes an insulating material.

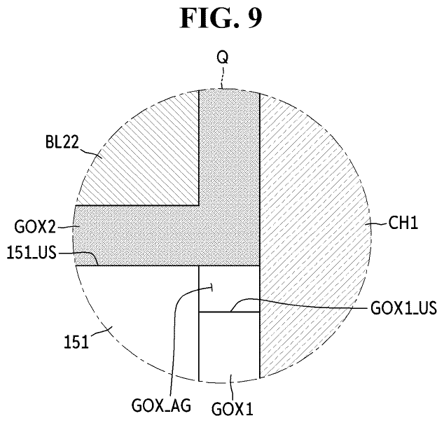

According to one or more example embodiments shown in FIG. 8, an upper side 151_US of the first isolation insulating pattern 151 may be disposed in the same plane as the uppermost side GOX1_US of the first lower gate insulating pattern GOX1. According to one or more example embodiments shown in FIG. 9, the upper side 151_US of the first isolation insulating pattern 151 may be higher than the uppermost side GOX1_US of the first lower gate insulating pattern GOX1.

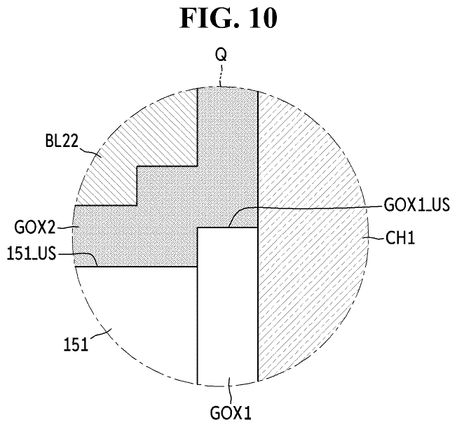

According to one or more example embodiments shown in FIG. 10, the upper side 151_US of the first isolation insulating pattern 151 may be lower than the uppermost side GOX1_US of the first lower gate insulating pattern GOX1. A part of the first lower gate insulating pattern GOX1 may protrude in the third direction DR3 beyond the upper side 151_US of the first isolation insulating pattern 151.

The first upper gate insulating pattern GOX2 may be disposed on the first lower word line WL11, the second lower word line WL12, and the first lower gate insulating pattern GOX1. The first upper gate insulating pattern GOX2 may be disposed on the first isolation insulating pattern 151.

The first upper gate insulating pattern GOX2 may extend along the second side wall CH1_VSW2 of the first vertical portion CH1_V1 of the first channel pattern CH1 and the second side wall CH1_VSW2 of the second vertical portion CH1_V2 of the first channel pattern CH1. The first upper gate insulating pattern GOX2 may extend along the upper side 151_US of the first isolation insulating pattern 151 and the first side 170_S1 of the first protruding insulating pattern 170.

The first upper gate insulating pattern GOX2 may be disposed between the first channel pattern CH1 and the second channel pattern CH2. The first upper gate insulating pattern GOX2 may be disposed between the first channel pattern CH1 and the second bit lines BL21 and BL22.

The first upper gate insulating pattern GOX2 may include a lower horizontal portion GOX2_H1, an upper horizontal portion GOX2_H2, and a vertical portion GOX2_V. The vertical portion GOX2_V of the first upper gate insulating pattern GOX2 may connect the lower horizontal portion GOX2_H1 of the first upper gate insulating pattern GOX2 to the upper horizontal portion GOX2_H2 of the first upper gate insulating pattern GOX2.

The lower horizontal portion GOX2_H1 of the first upper gate insulating pattern GOX2 may extend along the upper side 151_US of the first isolation insulating pattern 151. The upper horizontal portion GOX2_H2 of the first upper gate insulating pattern GOX2 may extend along the first side 170_S1 of the first protruding insulating pattern 170. The vertical portion GOX2_V of the first upper gate insulating pattern GOX2 may extend along the second side wall CH1_VSW2 of the first vertical portion CH1_V1 of the first channel pattern CH1 and the second side wall CH1_VSW2 of the second vertical portion CH1_V2 of the first channel pattern CH1. The vertical portion GOX2_V of the first upper gate insulating pattern GOX2 may be disposed between the first vertical portion CH1_V1 of the first channel pattern CH1 and the second vertical portion CH1_V2 of the first channel pattern CH1 that are adjacent to each other in the first direction DR1.

From the viewpoint of the cross-sectional views such as FIGS. 4 and 7, the lower horizontal portion GOX2_H1 of the first upper gate insulating pattern GOX2 and the upper horizontal portion GOX2_H2 of the first upper gate insulating pattern GOX2 may each extend in the first direction DR1. The vertical portion GOX2_V of the first upper gate insulating pattern GOX2 may extend in the third direction DR3.

The vertical portion GOX2_V of the first upper gate insulating pattern GOX2 may be disposed between the first channel pattern CH1 and the second channel pattern CH2. The vertical portion GOX2_V of the first upper gate insulating pattern GOX2 may be disposed between the first channel pattern CH1 and the second bit lines BL21 and BL22. The lower horizontal portion GOX2_H1 of the first upper gate insulating pattern GOX2 may be disposed between the first word lines WL11 and WL12 and the second bit lines BL21 and BL22.

The first upper gate insulating pattern GOX2 may be in contact with the first protruding insulating pattern 151. The lower horizontal portion GOX2_H1 of the first upper gate insulating pattern GOX2 may be in contact with the upper side 151_US of the first isolation insulating pattern 151.

The first upper gate insulating pattern GOX2 may be in contact with the first channel pattern CH1. The first upper gate insulating pattern GOX2 may be in contact with the first channel pattern CH1 disposed on the side wall of the first channel trench CH_T. The first upper gate insulating pattern GOX2 may be in contact with the first vertical portion CH1_V1 of the first channel pattern CH1 and the second vertical portion CH1_V2 of the first channel pattern CH1. The vertical portion GOX2_V of the first upper gate insulating pattern GOX2 may be in contact with the second side wall CH1_VSW2 of the first vertical portion CH1_V1 of the first channel pattern CH1 and the second side wall CH1_VSW2 of the second vertical portion CH1_V2 of the first channel pattern CH1.

According to one or more example embodiments shown in FIGS. 8 and 10, the first upper gate insulating pattern GOX2 may be in contact with the first lower gate insulating pattern GOX1. The lower horizontal portion GOX2_H1 of the first upper gate insulating pattern GOX2 may be in contact with the first lower gate insulating pattern GOX1. The first upper gate insulating pattern GOX2 may be in contact with the uppermost side GOX1_US of the first lower gate insulating pattern GOX1.

According to one or more example embodiments shown in FIG. 9, the first upper gate insulating pattern GOX2 may not be in contact with the first lower gate insulating pattern GOX1. From the viewpoint of the cross-sectional view, a gate insulating pattern air gap GOX_AG may be disposed between the first upper gate insulating pattern GOX2 and the first lower gate insulating pattern GOX1.

Unlike one or more example embodiments shown in FIG. 9, the first upper gate insulating pattern GOX2 may fill the space between the one of the plurality of first channel patterns CH1 and the first isolation insulating pattern 151. In such a case, the first upper gate insulating pattern GOX2 may be in contact with the uppermost side GOX1_US of the first lower gate insulating pattern GOX1.

The first upper gate insulating pattern GOX2 may include a ferroelectric material film (FE of FIG. 1). The ferroelectric material film FE may include at least one of a ferroelectric material or an antiferroelectric material. Hereinafter, for convenience of explanation, the antiferroelectric material is also described as being a ferroelectric material.

The ferroelectric material film FE may include, for example, at least one of hafnium oxide, hafnium zirconium oxide, barium strontium titanium oxide, barium titanium oxide or lead zirconium titanium oxide. According to one or more example embodiments, hafnium zirconium oxide may be a material in which hafnium oxide is doped with zirconium (Zr). As another example, hafnium zirconium oxide may be a compound of hafnium (Hf), zirconium (Zr), and oxygen (O).

The ferroelectric material film FE may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). The type of dopant included in the ferroelectric material film FE may vary, depending on which type of ferroelectric material is included in the ferroelectric material film FE.

When the ferroelectric material film FE includes hafnium oxide, the dopant included in the ferroelectric material film FE may include, for example, at least one of gadolinium (Gd), silicon (Si), zirconium (Zr), aluminum (Al) or yttrium (Y).

When the dopant is aluminum (Al), the ferroelectric material film FE may include 3 to 8 at % (atomic %) aluminum. According to one or more example embodiments, a ratio of the dopant may be a ratio of aluminum to the sum of hafnium and aluminum.

When the dopant is silicon (Si), the ferroelectric material film FE may include 2 to 10 at % silicon. When the dopant is yttrium (Y), the ferroelectric material film FE may include 2 to 10 at % yttrium. When the dopant is gadolinium (Gd), the ferroelectric material film FE may include 1 to 7 at % gadolinium. When the dopant is zirconium (Zr), the ferroelectric material film FE may include 50 to 80 at % zirconium.

The ferroelectric material film FE may have a thickness having ferroelectric properties. A thickness of the ferroelectric material film may be, for example, but is not limited to, 0.5 to 10 nm. Because a critical thickness that exhibits the ferroelectric properties may vary for each ferroelectric material, the thickness of the ferroelectric material film FE may vary depending on the ferroelectric material.

The first upper gate insulating pattern GOX2 may correspond to the ferroelectric material film FE connected to the gate terminal of the read transistor RTR. In addition, the first upper gate insulating pattern GOX2 may function as a gate insulating film of the read transistor RTR. That is, the first upper gate insulating pattern GOX2 may function as a gate of the read transistor RTR and may also function as a gate insulating film of the read transistor RTR.

The second bit lines BL21 and BL22 may be disposed on the first word lines WL11 and WL12. The second bit lines BL21 and BL22 may be spaced apart from the first word lines WL11 and WL12 in the third direction DR3. The second bit lines BL21 and BL22 may be disposed on the first upper gate insulating pattern GOX2.

The second bit lines BL21 and BL22 may be disposed inside the first channel trench CH_T. The second bit lines BL21 and BL22 may be disposed between the first vertical portion CH1_V1 of the first channel pattern CH1 and the second vertical portion CH1_V2 of the first channel pattern CH1. The second bit lines BL21 and BL22 may be disposed between the vertical portions GOX2_V of the first upper gate insulating patterns GOX2 adjacent to each other in the first direction DR1.

The second bit lines BL21 and BL22 may include a first upper bit line BL21 and a second upper bit line BL22. Each of the first upper bit line BL21 and the second upper bit line BL22 may extend in the second direction DR2. A plurality of the first upper bit lines BL21 and the second upper bit lines BL22 may be arranged alternately in the first direction DR1. The first upper bit lines BL21 and the second upper bit lines BL22 may be spaced apart from each other in the first direction DR1.

The first vertical portion CH1_V1 of the first channel pattern CH1 may be disposed closer to the first upper bit line BL21 than to the second upper bit line BL22. The first upper bit line BL21 may be disposed on a second side wall CH1_VSW2 of the first vertical portion CH1_V1 of the first channel pattern CH1. The second vertical portion CH1_V2 of the first channel pattern CH1 may be disposed closer to the second upper bit line BL22 than to the first upper bit line BL21. The second upper bit line BL22 may be disposed on a second side wall CH1_VSW2 of the second vertical portion CH1_V2 of the first channel pattern CH1.

The first upper bit line BL21 may not be disposed on the first side wall CH1_VSW1 of the first vertical portion CH1_V1 of the first channel pattern CH1. The second upper bit line BL22 may not be disposed on the first side wall CH1_VSW1 of the second vertical portion CH1_V2 of the first channel pattern CH1.

The first upper bit line BL21 and the first lower word line WL11 may be spaced apart from each other in the third direction DR3. At least a part of the first upper bit line BL21 may overlap the first lower word line WL11 in the third direction DR3.

The second upper bit line BL22 and the second lower word line WL12 may be spaced apart from each other in the third direction DR3. At least a part of the second upper bit line BL22 may overlap the second lower word line WL12 in the third direction DR3. The lower horizontal portion GOX2_H1 of the first upper gate insulating pattern GOX2 may be disposed between the first upper bit line BL21 and the first lower word line WL11, and between the second upper bit line BL22 and the second lower word line WL12.

The second bit lines BL21 and BL22 may include a conductive material, and may include at least one of, for example, a doped semiconductor material, a conductive metal nitride, a conductive metal silicon nitride, a metal carbonitride, a conductive metal silicide, a conductive metal oxide, a two-dimensional material, and a metal. Although the second bit lines BL21 and BL22 are shown as being a single film, one or more example embodiments are not limited thereto.

A second isolation insulating pattern 152 may be disposed on the first upper gate insulating pattern GOX2. The second isolation insulating pattern 152 may be disposed inside the first channel trench CH_T.

The second isolation insulating pattern 152 may be disposed between the first upper bit line BL21 and the second upper bit line BL22 adjacent to each other in the first direction DR1. The second isolation insulating pattern 152 may include an insulating film.

The second channel pattern CH2 may be disposed on the second bit lines BL21 and BL22. The second channel pattern CH2 may be in contact with the second bit lines BL21 and BL22. The second channel pattern CH2 may be electrically connected to the second bit lines BL21 and BL22.

The second channel pattern CH2 may include an upper horizontal portion CH2_H1 and a plurality of vertical portions CH2_V1 and CH2_V2. The vertical portions CH2_V1 and CH2_V2 of the second channel pattern CH2 may protrude from the upper horizontal portion CH2_H1 of the second channel pattern CH2 toward the first bit line BL1.

The upper horizontal portion CH2_H1 of the second channel pattern CH2 may extend in the first direction DR1. The upper horizontal portion CH2_H1 of the second channel pattern CH2 may be disposed on the first side 170_S1 of the first protruding insulating pattern 170. The upper horizontal portion CH2_H1 of the second channel pattern CH2 may be spaced apart from the first channel pattern CH1 in the third direction DR3.

The vertical portions CH2_V1 and CH2_V2 of the second channel pattern CH2 may extend in the third direction DR3. The vertical portions CH2_V1 and CH2_V2 of the second channel pattern CH2 may be directly connected to the upper horizontal portion CH2_H1 of the second channel pattern CH2. The vertical portions CH2_V1 and CH2_V2 of the second channel pattern CH2 may be disposed inside the first channel trench CH_T.

The vertical portions CH2_V1 and CH2_V2 of the second channel pattern CH2 may include a first vertical portion CH2_V1 and a second vertical portion CH2_V2. The first vertical portion CH2_V1 of the second channel pattern CH2 and the second vertical portion CH2_V2 of the second channel pattern CH2 may be arranged alternately in the first direction DR1. The first vertical portion CH2_V1 of the second channel pattern CH2 and the second vertical portion CH2_V2 of the second channel pattern CH2 may be spaced apart from each other in the first direction DR1.

The first vertical portion CH2_V1 of the second channel pattern CH2 may be in contact with the first upper bit line BL21. The second vertical portion CH2_V2 of the second channel pattern CH2 may be in contact with the second upper bit line BL22.

Each of the first vertical portion CH2_V1 of the second channel pattern CH2 and the second vertical portion CH2_V2 of the second channel pattern CH2 may overlap the first channel pattern CH1 in the first direction DR1. For example, the first vertical portion CH2_V1 of the second channel pattern CH2 and the second vertical portion CH2_V2 of the second channel pattern CH2 may overlap the vertical portions CH1_V1 and CH1_V2 of the first channel pattern in the first direction DR1.

The first vertical portion CH2_V1 of the second channel pattern CH2 may be disposed on the second side wall CH1_VSW2 of the first vertical portion CH1_V1 of the first channel pattern. The second vertical portion CH2_V2 of the second channel pattern CH2 may be disposed on the second side wall CH1_VSW2 of the second vertical portion CH1_V2 of the first channel pattern CH1.

The upper horizontal portion CH2_H1 of the second channel pattern CH2 may be formed at a different level from the vertical portions CH2_V1 and CH2_V2 of the second channel pattern CH2.

According to one or more example embodiments, the second channel pattern CH2 may include an oxide semiconductor material or a two-dimensional semiconductor material like the first channel pattern CH1. For example, the upper horizontal portion CH2_H1 of the second channel pattern CH2 may include the same oxide semiconductor material as the vertical portions CH2_V1 and CH2_V2 of the second channel pattern CH2. For example, the upper horizontal portion CH2_H1 of the second channel pattern CH2 may include an oxide semiconductor material different from the vertical portions CH2_V1 and CH2_V2 of the second channel pattern CH2.

As another example, the second channel pattern CH2 may include a material different from the first channel pattern CH1. For example, the first channel pattern CH1 may include an oxide semiconductor material, and the second channel pattern CH2 may include polycrystalline silicon. The polycrystalline silicon may include, but is not limited to, a doped impurity element.

As yet another example, the upper horizontal portion CH2_H1 of the second channel pattern CH2 may include an oxide semiconductor material or a two-dimensional semiconductor material. The vertical portions CH2_V1 and CH2_V2 of the second channel pattern CH2 may include polycrystalline silicon.

As yet another example, the vertical portions CH2_V1 and CH2_V2 of the second channel pattern CH2 may include an oxide semiconductor material or a two-dimensional semiconductor material. The upper horizontal portion CH2_H1 of the second channel pattern CH2 may include polycrystalline silicon.

A third isolation insulating pattern 153 may be disposed on the second isolation insulating pattern 152. The third isolation insulating pattern 153 may be disposed inside the one of the first channel trenches CH_T. The upper horizontal portion CH2_H1 of the second channel pattern CH2 may be disposed on the third isolation insulating pattern 153.

The third isolation insulating pattern 153 may be disposed between the first vertical portion CH2_V1 of the second channel pattern CH2 and the second vertical portion CH2_V2 of the second channel pattern CH2 that are adjacent to each other in the first direction DR1. The third isolation insulating pattern 153 includes an insulating material.

The second word line WL2 may be disposed on the second channel pattern CH2. The second word line WL2 may be disposed on the first side 170_S1 of the first protruding insulating pattern 170.

A plurality of second word lines WL2 may extend in the first direction DR1. The second word lines WL2 may be adjacent to each other in the second direction DR2.

The second word line WL2 may include a first side WL2_S1 and a second side WL2_S2 that are opposite to each other in the third direction DR3. The second side WL2_S2 of the second word line WL2 may face the second channel pattern CH2.

The second word line WL2 may be connected to the second channel pattern CH2. For example, the second word line WL2 may be connected to the upper horizontal portion CH2_H1 of the second channel pattern CH2. The second side WL2_S2 of the second word line WL2 may be connected to the upper horizontal portion CH2_H of the second channel pattern CH2. The second word line WL2 may be in contact with the upper horizontal portion CH2_H of the second channel pattern CH2.

As an example, each of the first upper bit line BL21 and the second upper bit line BL22 may correspond to the read bit line RBL of the read transistor RTR of FIG. 1. The second word line WL2 may correspond to the read word line RWL of the read transistor RTR in FIG. 1.

As another example, each of the first upper bit line BL21 and the second upper bit line BL22 may correspond to the read word line RWL of the read transistor RTR of FIG. 1. The second word line WL2 may correspond to the read bit line RBL of the read transistor RTR of FIG. 1.

The second word line WL2 may include a conductive material, and may include at least one of, for example, a doped semiconductor material, a conductive metal nitride, a conductive metal silicon nitride, a conductive metal carbonitride, a conductive metal silicide, a conductive metal oxide, a two-dimensional material or a metal. The second word line WL2 is shown as being a single film, but one or more example embodiments are not limited thereto.

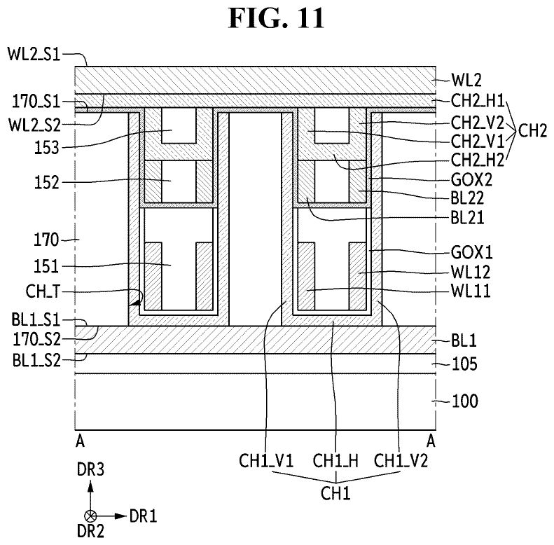

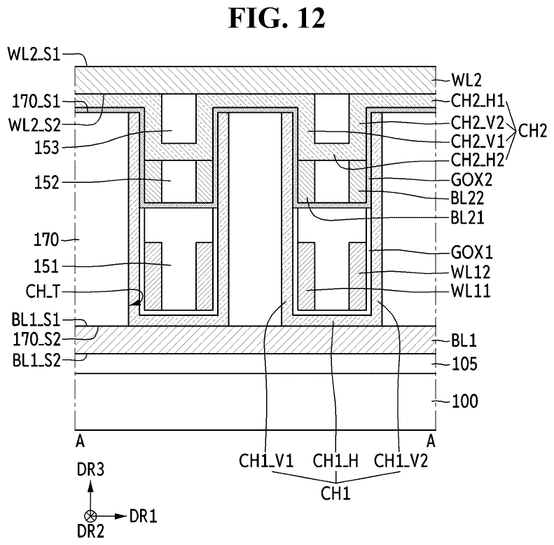

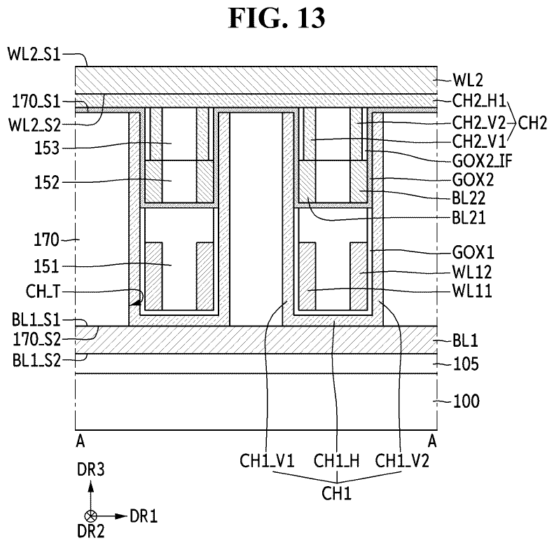

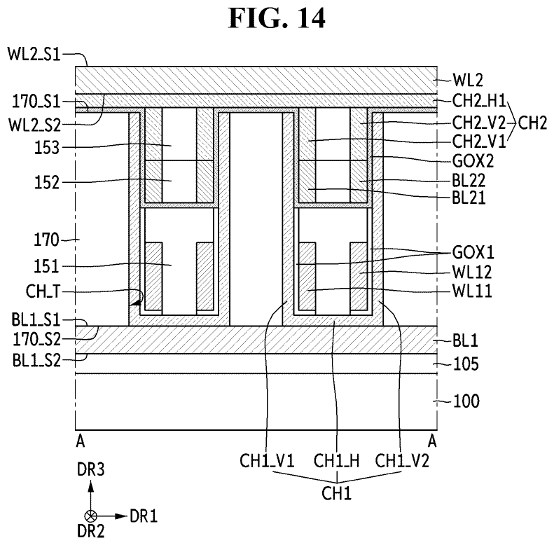

FIGS. 11 and 12 are diagrams for explaining a semiconductor device according to one or more example embodiments. FIGS. 13 and 14 are diagrams for explaining the semiconductor device according to one or more example embodiments. For convenience of explanation, differences from those one or more example embodiments described using FIGS. 2, 3, 4, 5, 6, 7, 8, 9 and 10 will be mainly described.

Referring to FIGS. 11 and 12, in the semiconductor device according to one or more example embodiments, the second channel pattern CH2 may further include a lower horizontal portion CH2_H2.

The lower horizontal portion CH2_H2 of the second channel pattern CH2 may be disposed inside the first channel trench CH_T. The lower horizontal portion CH2_H2 of the second channel pattern CH2 may be disposed between the second isolation insulating pattern 152 and the third isolation insulating pattern 153. The third isolation insulating pattern 153 may be disposed on the lower horizontal portion CH2_H2 of the second channel pattern CH2.

The lower horizontal portion CH2_H2 of the second channel pattern CH2 may be directly connected to the first vertical portion CH2_V1 of the second channel pattern CH2 and the second vertical portion CH2_V2 of the second channel pattern CH2. The lower horizontal portion CH2_H2 of the second channel pattern CH2 may include the same material as the first vertical portion CH2_V1 of the second channel pattern CH2 and the second vertical portion CH2_V2 of the second channel pattern CH2. The lower horizontal portion CH2_H2 of the second channel pattern CH2 may be formed at the same level as the vertical portions CH2_V1 and CH2_V2 of the second channel pattern CH2. According to one or more example embodiments, “the same level” means that they are formed by the same fabricating process.

In FIG. 11, the first vertical portion CH2_V1 of the second channel pattern CH2 and the second vertical portion CH2_V2 of the second channel pattern CH2 may be connected by the upper horizontal portion CH2_H1 of the second channel pattern CH2 on the first side 170_S1 of the first protruding insulating pattern 170. From the viewpoint of the cross-sectional view, the third isolation insulating pattern 153 may be disposed between the upper horizontal portion CH2_H1 of the second channel pattern CH2 and the lower horizontal portion CH2_H2 of the second channel pattern CH2.

According to one or more example embodiments shown in FIG. 12, the first vertical portion CH2_V1 of the second channel pattern CH2 and the second vertical portion CH2_V2 of the second channel pattern CH2 may not be connected by the upper horizontal portion CH2_H1 of the second channel pattern CH2 on the first side 170_S1 of the first protruding insulating pattern 170. From the viewpoint of the cross-sectional view, the third isolation insulating pattern 153 may extend up to the second side WL2_S2 of the second word line WL2. For example, the upper horizontal portion CH2_H1 of the second channel pattern CH2, the lower horizontal portion CH2_H2 of the second channel pattern CH2, and the vertical portions CH2_V1 and CH2_V2 of the second channel pattern CH2 may be formed at the same level.

Referring to one or more example embodiments shown in FIG. 13, a semiconductor device according to one or more example embodiments may further include an insertion gate insulating pattern GOX2_IF.

The insertion gate insulating pattern GOX2_IF may be disposed between the first upper gate insulating pattern GOX2 and the first vertical portion CH2_V1 of the second channel pattern CH2, and between the first upper gate insulating pattern GOX2 and the second vertical portion CH2_V2 of the second channel pattern CH2.

The insertion gate insulating pattern GOX2_IF may include, for example, silicon oxide. The vertical portions CH2_V1 and CH2_V2 of the second channel pattern CH2 may include polycrystalline silicon.

Referring to one or more example embodiments shown in FIG. 14, in the semiconductor device according to one or more example embodiments, the one of the plurality of first channel patterns CH1 and the first lower gate insulating pattern GOX1 of the first lower word line WL11 may be separated from the first lower gate insulating pattern GOX1 between the first channel pattern CH1 and the second lower word line WL12.

The first isolation insulating pattern 151 may be in contact with the first channel pattern CH1. The first isolation insulating pattern 151 may be in contact with the horizontal portion CH1_H of the first channel pattern.

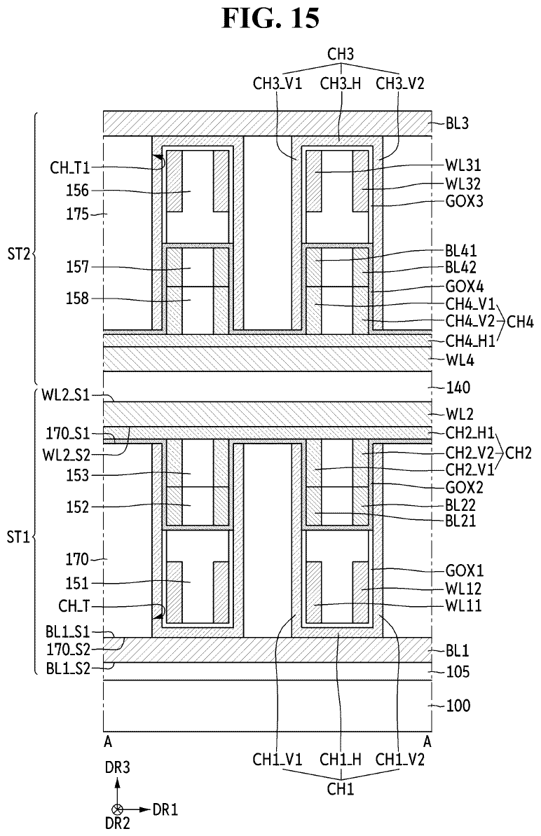

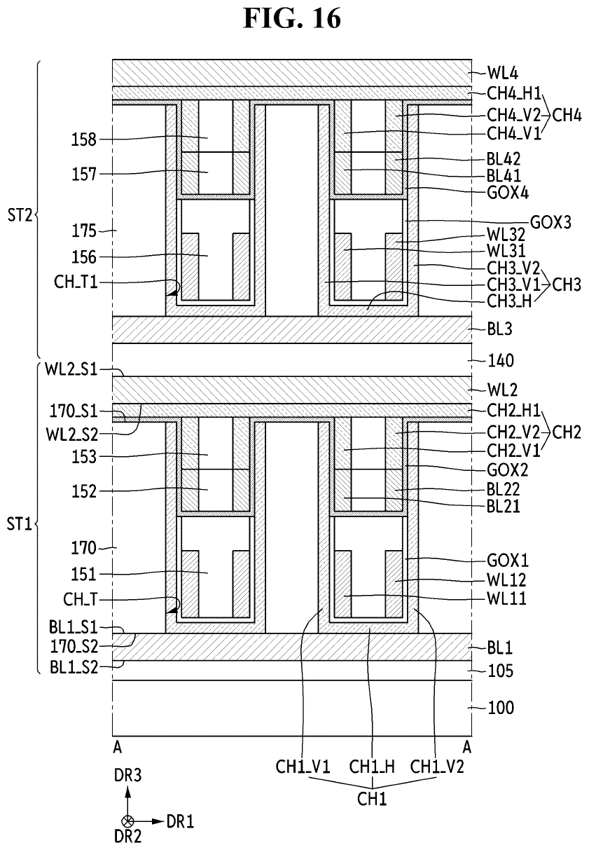

FIGS. 15 and 16 are diagrams for explaining semiconductor devices according to one or more example embodiments. For convenience of explanation, differences from those one or more example embodiments described using FIGS. 2, 3, 4, 5, 6, 7, 8, 9 and 10 will be mainly explained.

Referring to FIGS. 15 and 16, the semiconductor device according to one or more example embodiments may include a first memory structure ST1 and a second memory structure ST2 that are stacked in the third direction DR3.

The second memory structure ST2 may be disposed on the first memory structure ST1.

For example, the semiconductor device described above referring to one or more example embodiments shown in FIGS. 2, 3, 4, 5, 6, 7, 8, 9 and 10 may constitute the first memory structure ST1. In other words, the first memory structure ST1 may include a first bit line BL1, first word lines WL11 and WL12, second bit lines BL21 and BL22, a second word line WL2, a first channel pattern CH1, a second channel pattern CH2, a first lower gate insulating pattern GOX1, and a second upper gate insulating pattern GOX2.

The following description will focus on the second memory structure ST2.

The second memory structure ST2 may include a third bit line BL3, third word lines WL31 and WL32, fourth bit lines BL41 and BL42, a fourth word line WL4, a third channel pattern CH3, a fourth channel pattern CH4, a second lower gate insulating pattern GOX3, and a second upper gate insulating pattern GOX4.

The description of the third bit line BL3, the third word lines WL31 and WL32, the fourth bit lines BL41 and BL42, the fourth word line WL4, the third channel pattern CH3, and the fourth channel pattern CH4 included in the second memory structure ST2 may be substantially the same as the description of the first bit line BL1, the first word lines WL11 and WL12, the second bit lines BL21 and BL22, the second word line WL2, the first channel pattern CH1, and the second channel pattern CH2 included in the first memory structure ST1. The description of the second lower gate insulating pattern GOX3 may be substantially the same as the description of the first lower gate insulating pattern GOX1. The description of the second upper gate insulating pattern GOX4 may be substantially the same as the description of the first upper gate insulating pattern GOX2.

The third channel pattern CH3 may include a horizontal portion CH3_H, a first vertical portion CH3_V1, and a second vertical portion CH3_V2. The fourth channel pattern CH4 may include an upper horizontal portion CH4_H1, a first vertical portion CH4_V1, and a second vertical portion CH4_V2.

The second lower gate insulating pattern GOX3 may be disposed between the third channel pattern CH3 and the third word lines WL31 and WL32. The second lower gate insulating pattern GOX3 may extend along a part of the profile of the third channel pattern CH3.

The second upper gate insulating pattern GOX4 may be disposed between the third channel pattern CH3 and the fourth channel pattern CH4. The second upper gate insulating pattern GOX4 may be disposed between the third channel pattern CH3 and the fourth bit lines BL41 and BL42. The second upper gate insulating pattern GOX4 may be disposed between the third word lines WL31 and WL32 and the fourth bit lines BL41 and BL42.

The second protruding insulating pattern 175 may include a second channel trench CH_T1 extending in the second direction DR2. The third word lines WL31 and WL32, the fourth bit lines BL41 and BL42, the third channel pattern CH3, and the vertical portions CH4_V1 and CH4_V2 of the fourth channel pattern CH4 may be provided.

Each of a fourth isolation insulating pattern 156, a fifth isolation insulating pattern 157, and a sixth isolation insulating pattern 158 may be disposed in the second channel trench CH_T1.

According to one or more example embodiments shown in FIG. 15, the second memory structure ST2 including the third bit line BL3, the third word lines WL31 and WL32, the fourth bit lines BL41 and BL42, and the fourth word line WL4 may be formed sequentially on a supporting substrate. The supporting substrate including the second memory structure ST2 may be bonded to the substrate 100. The supporting substrate may then be removed. An insertion interlayer insulating film 140 may be disposed between the supporting substrate and the substrate 100 to bond the supporting substrate and the substrate 100. Accordingly, the second word line WL2 and the fourth word line WL4 may be disposed between the second channel pattern CH2 and the fourth channel pattern CH4. The insertion interlayer insulating film 140 includes an insulating material.

Unlike one or more example embodiments shown in FIG. 15, the insertion interlayer insulating film 140 may not be disposed between the second word line WL2 and the fourth word line WL4. The second word line WL2 and the fourth word line WL4 may be in contact with each other. The supporting substrate and the substrate 100 may be bonded by the second word line WL2 and the fourth word line WL4.

According to one or more example embodiments shown in FIG. 16, a second memory structure ST2 may be formed on the substrate 100 with the first memory structure ST1 formed thereon. The third bit line BL3 may be disposed between the second word line WL2 and the third channel pattern CH3.

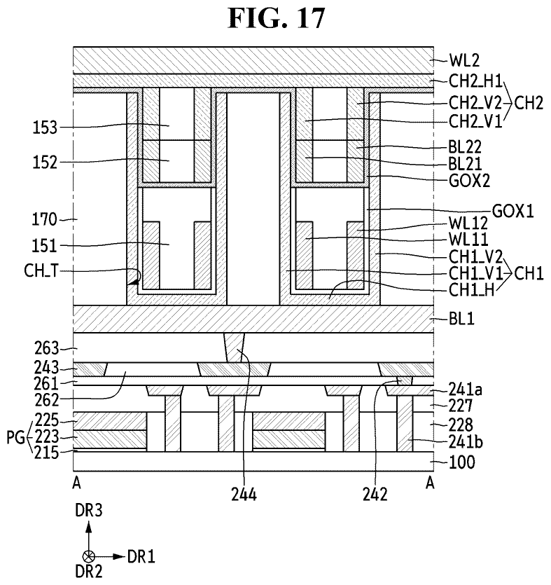

FIG. 17 is a diagram for explaining a semiconductor device according to one or more example embodiments. For convenience of explanation, differences from those one or more example embodiments described using FIGS. 1, 2, 3, 4, 5, 6, 7, 8, 9 and 10 will be mainly explained.

Referring to FIG. 17, the semiconductor device according to one or more example embodiments may further include a peri-gate structure PG.

The peri-gate structure PG may be disposed on the substrate 100. The peri-gate structure PG may be included in a sensing transistor, a transfer transistor, a driving transistor, or the like. According to one or more example embodiments, the types of transistors disposed in the cell array region and the peripheral circuit region may vary depending on the design placement of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than that of the silicon oxide film, or a combination thereof. The high dielectric constant insulating film may include, for example, but is not limited to, at least one of a metal oxide, a metal oxynitride, a metal silicon oxide, and a metal silicon oxynitride.

Each of the peri-lower conductive pattern 223 and the peri-upper conductive pattern 225 may include a conductive material. For example, each of the peri-lower conductive pattern 223 and the peri-upper conductive pattern 225 may include at least one of a doped semiconductor material, a conductive metal nitride, a conductive metal silicon nitride, a conductive metal carbonitride, a conductive metal silicide, a conductive metal oxide, a two-dimensional material or a metal. The peri-gate structure PG is shown to include, but is not limited to, a plurality of conductive patterns.

A first peri-lower insulating film 227 and a second peri-lower insulating film 228 are disposed on the substrate 100. Each of the first peri-lower insulating film 227 and the second peri-lower insulating film 228 may comprise an insulating material.

A first peri-wiring line 241a and a peri-contact plug 241b may be disposed inside the first peri-lower insulating film 227 and the second peri-lower insulating film 228. The first peri-wiring line 241a and the peri-contact plug 241b are shown as being different films from each other, but are not limited thereto. A boundary between the first peri-wiring line 241a and the peri-contact plug 241b may not be divided. Each of the first peri-wiring line 241a and the peri-contact plug 241b may include a conductive material.

The first peri-upper insulating film 261 and the second peri-upper insulating film 262 may be disposed on the first peri-wiring line 241a and the peri-contact plug 241b. Each of the first peri-upper insulating film 261 and the second peri-upper insulating film 262 may comprise an insulating material.

A second peri-wiring line 243 and a peri-via plug 242 may be disposed on the first peri-wiring line 241a. The peri-via plug 242 may be disposed inside the first peri-upper insulating film 261. The second peri-wiring line 243 may be disposed inside the second peri-upper insulating film 262.

The second peri-wiring line 243 and the peri-via plug 242 may be connected to the first peri-wiring line 241a. The peri-via plug 242 may connect the first peri-wiring line 241a and the second peri-wiring line 243. The second peri-wiring line 243 and the peri-via plug 242 may each include a conductive material. The second peri-wiring line 243 and the peri-via plug 242 are shown as being different films from each other, but one or more example embodiments are not limited thereto. The boundary between the second peri-wiring line 243 and the peri-via plug 242 may not be divided.

The first bit line BL1, the first word lines WL11 and WL12, the second bit lines BL21 and BL22, the second word line WL2, the first channel pattern CH1, the second channel pattern CH2, the first lower gate insulating pattern GOX1, and the first upper gate insulating pattern GOX2 may be disposed on the peri-gate structure PG.

A cell connection plug 244 may be disposed inside the third peri-upper insulating film 263. The cell connection plug 244 may be connected to the second peri-wiring line 243. The cell connection plug 244 may include a conductive material. The third peri-upper insulating films 263 may each include an insulating material.

The first bit line BL1 may be disposed on the cell connection plug 244. The first bit line BL1 may be connected to the cell connection plug 244. The first word lines WL11 and WL12, the second bit lines BL21 and BL22, and the second word line WL2 may be connected to the second peri-wiring line 243.

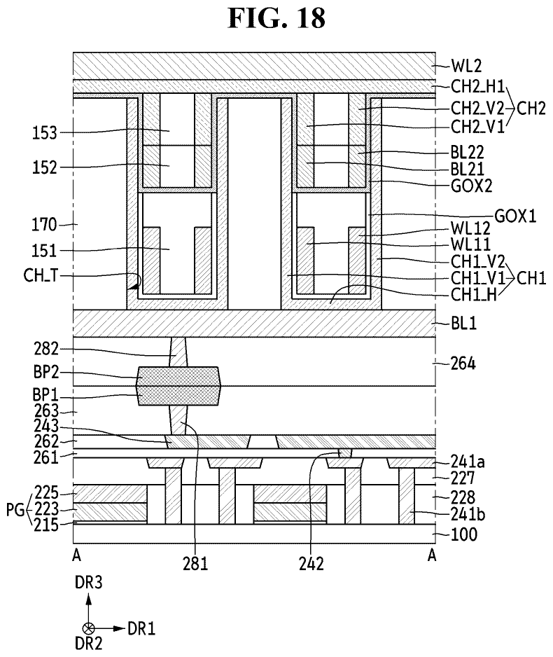

FIG. 18 is a diagram for explaining a semiconductor memory device according to one or more example embodiments. For convenience of explanation, differences from those one or more example embodiments described using FIG. 17 will be mainly described.

Referring to FIG. 18, the semiconductor memory device according to one or more example embodiments may further include a first bonding pad BP1 and a second bonding pad BP2.

The first bonding pad BP1 and the first pad plug 281 may be disposed on the second peri-wiring line 243. The first bonding pad BP1 and the first pad plug 281 may be disposed inside the third peri-upper insulating film 263.

The first pad plug 281 may be disposed between the first bonding pad BP1 and the second peri-wiring line 243. The first pad plug 281 may connect the first bonding pad BP1 and the second peri-wiring line 243.

The second bonding pad BP2 and the second pad plug 282 may be disposed on the first bonding pad BP1. The second bonding pad BP2 and the second pad plug 282 may be disposed inside the fourth peri-upper insulating film 264.

The second bonding pad BP2 may be connected to the first bonding pad BP1. For example, the second bonding pad BP2 may be in contact with the first bonding pad BP1. Because the second bonding pad BP2 is electrically connected to the first bonding pad BP1, the second bonding pad BP2 may be connected to the peri-wiring lines 241a and 243.

The first bit line BL1 may be disposed on the second bonding pad BP2. The second pad plug 282 may be disposed between the first bit line BL1 and the second bonding pad BP2. The second pad plug 282 may connect the first bit line BL1 and the second bonding pad BP2.

Because the second bonding pad BP2 is connected to the first bonding pad BP1, the peri-wiring lines 241a and 243 may be connected to the first bit line BL1. The first word lines WL11 and WL12, the second bit lines BL21 and BL22, and the second word line WL2 may be connected to the second bonding pad BP2.

The first pad plug 281 and the second pad plug 282 may include a conductive material including a metal. The first bonding pad BP1 and the second bonding pad BP2 may each include a conductive material including a metal. Although the first bonding pad BP1 and the second bonding pad BP2 are each shown as being a single film, this is only for convenience of explanation, and one or more example embodiments are not limited thereto.

A fourth peri-upper insulating film 264 may include an insulating material. Although the boundary between the third peri-upper insulating film 263 and the fourth peri-upper insulating film 264 is shown as being divided, this is only for convenience of explanation, and one or more example embodiments are not limited thereto. If the third peri-upper insulating film 263 and the fourth peri-upper insulating film 264 include the same material, the boundary between the third peri-upper insulating film 263 and the fourth peri-upper insulating film 264 may not be divided. According to one or more example embodiments, the boundary between the third peri-upper insulating film 263 and the fourth peri-upper insulating film 264 may be divided, using the boundary between the first bonding pad BP1 and the second bonding pad BP2.

A bonding insulating film may be further disposed between the third peri-upper insulating film 263 and the fourth peri-upper insulating film 264. For example, the bonding insulating film may include, but is not limited to, SiCN.

Unlike one or more example embodiments shown in FIG. 18, the second word line WL2 may be disposed on the second bonding pad BP2. The second pad plug 282 may be disposed between the second word line WL2 and the second bonding pad BP2. The second pad plug 282 may connect the second word line WL2 and the second bonding pad BP2. In other words, a memory cell having the shape of the second memory structure ST2 of FIG. 15 may be disposed on the second bonding pad BP2.

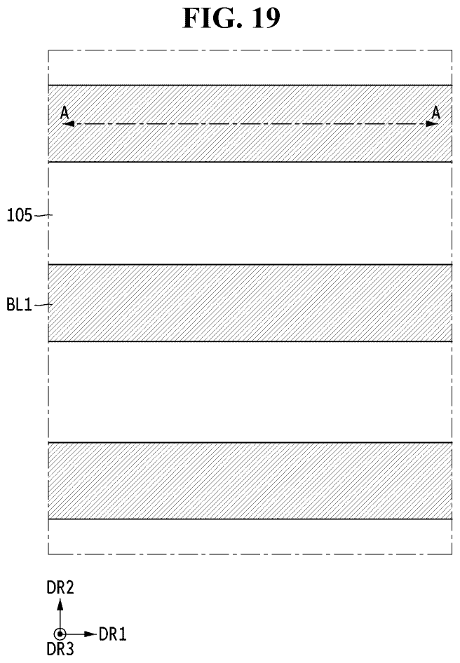

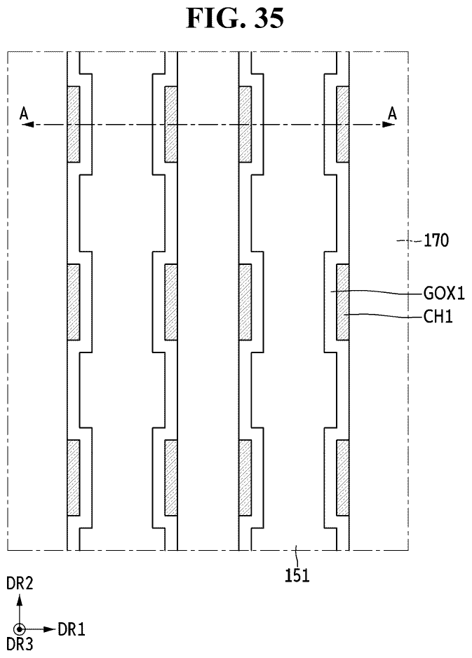

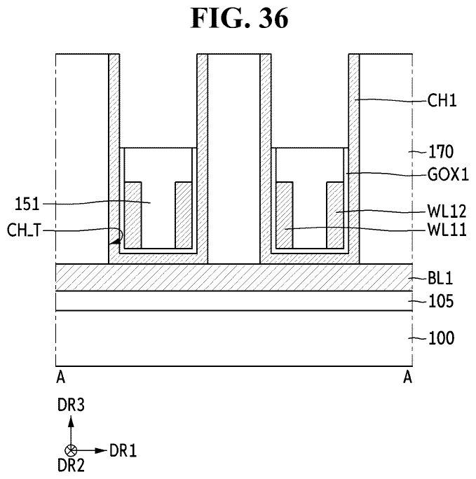

FIGS. 19, 20, 21, 22, 23, 24, 25, 26, 27, 28, 29, 30, 31, 32, 33, 34, 35, 36, 37, 38, 39, 40 and 41 are intermediate stage diagrams for explaining a semiconductor device according to one or more example embodiments. To simplify the explanation, the explanation of the repeated contents of the above contents will be simplified or omitted.

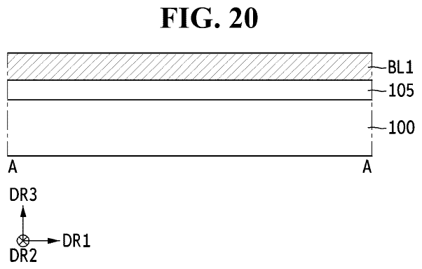

Referring to one or more example embodiments shown in FIGS. 19 and 20, the first bit line BL1 may be formed on the substrate 100.

As an example, a first portion of the lower insulating film 105 may be formed on the substrate 100. The lower conductive line film may be formed on the first portion of the lower insulating film 105. The lower conductive line film may be patterned to form the first bit line BL1. Next, a second portion of the lower insulating film 105 may be formed between the first bit lines BL1 adjacent to each other in the second direction DR2. The lower insulating film 105 may be formed, accordingly.

As another example, the lower insulating film 105 may be formed on the substrate 100. A lower conductive line trench may be formed inside the lower insulating film 105. Next, the first bit line BL1 that fills the lower conductive line trench may be formed.

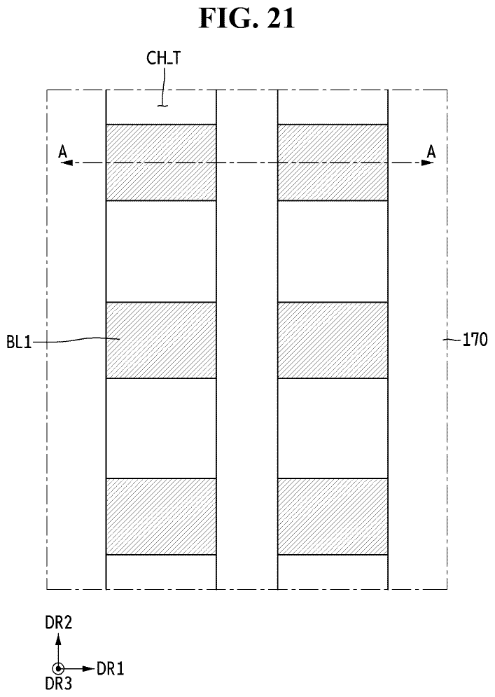

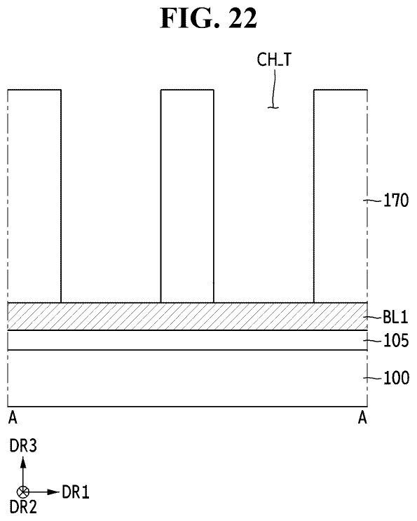

Referring to one or more example embodiments shown in FIGS. 21 and 22, the first protruding insulating pattern 170 may be formed on the first bit line BL1.

The first protruding insulating pattern 170 may include a plurality of first channel trenches CH_T that expose the first bit line BL1.

More specifically, a protruding insulating film may be formed on the first bit line BL1. The first channel trench CH_T may be formed inside the protruding insulating film. The first protruding insulating pattern 170 may be formed, accordingly.

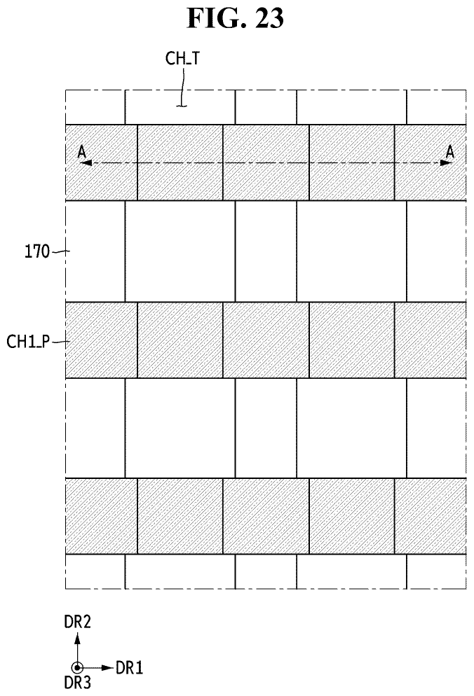

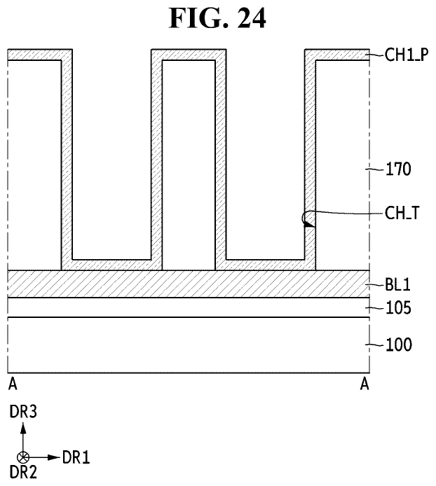

Referring to one or more example embodiments shown in FIGS. 23 and 24, a plurality of pre-channel patterns CH1_P may be formed along the side walls and bottom sides of the first channel trench CH_T.

The plurality of pre-channel patterns CH1_P may be formed along the upper side of the first protruding insulating pattern 170. Each of the pre-channel patterns CH1_P may be spaced apart in the second direction DR2.

More specifically, a pre-channel film may be formed on the first protruding insulating pattern 170. The pre-channel film may be entirely formed on the side walls and bottom side of the first channel trench CH_T. The pre-channel film may entirely cover the upper side of the first protruding insulating pattern 170. The pre-channel film may then be patterned, using a photo process. The pre-channel pattern CH1_P extending in the first direction DR1 may be formed, accordingly.

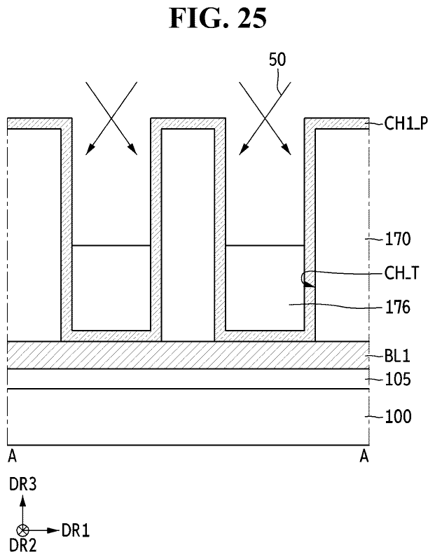

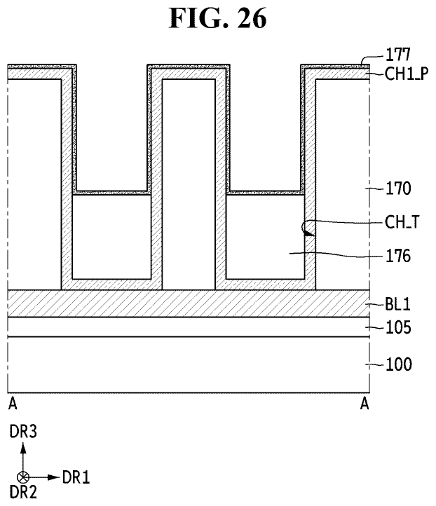

Referring to one or more example embodiments shown in FIGS. 25 and 26, a sacrificial pattern 176 may be formed on the pre-channel pattern CH1_P.

The sacrificial pattern 176 may fill a part of the first channel trench CH_T.

In FIG. 25, after the sacrificial pattern 176 is formed, an implant process 50 may be performed. The implant process 50 may inject materials, such as boron (B), argon (Ar), and/or fluorine (F), into the pre-channel pattern CH1_P. The implant process 50 may be performed in a tilted state. Because the sacrificial pattern 176 serves as a mask, the portion of the pre-channel pattern CH1_P that is blocked by the sacrificial pattern 176 may not be affected by the implant process 50. That is, a physical damage may be applied to a part of the pre-channel pattern CH1_P through the implant process 50. While the implant process 50 is performed, the pre-channel pattern CH1_P blocked by the sacrificial pattern 176 may not be physically damaged by the implant process 50. Oxygen may escape from the pre-channel pattern CH1_P that is physically damaged through the implant process 50. As a result, a portion with a relatively low oxygen concentration may be formed inside the pre-channel pattern CH1_P.

Accordingly, the portion with a relatively low oxygen concentration in the pre-channel pattern CH1_P may have metallic properties compared to other portions.

According to one or more example embodiments shown in FIG. 26, an impurity film 177 may be formed on the pre-channel pattern CH1_P and the sacrificial pattern 176. The impurity film 177 may be in direct contact with the pre-channel pattern CH1_P that is not covered with the sacrificial pattern 176. The impurity film 177 may include, for example, boron (B). After forming the impurity film 177, the boron (B) contained in the impurity film 177 may be diffused into the pre-channel pattern CH1_P that is not covered with the sacrificial pattern 176 through a thermal process. Accordingly, the portion in which boron B is diffused in the pre-channel pattern CH1_P may have relatively more metallic properties than the portion in which no boron is diffused.

Thereafter, the sacrificial pattern 176 on the pre-channel pattern CH1_P may be removed.

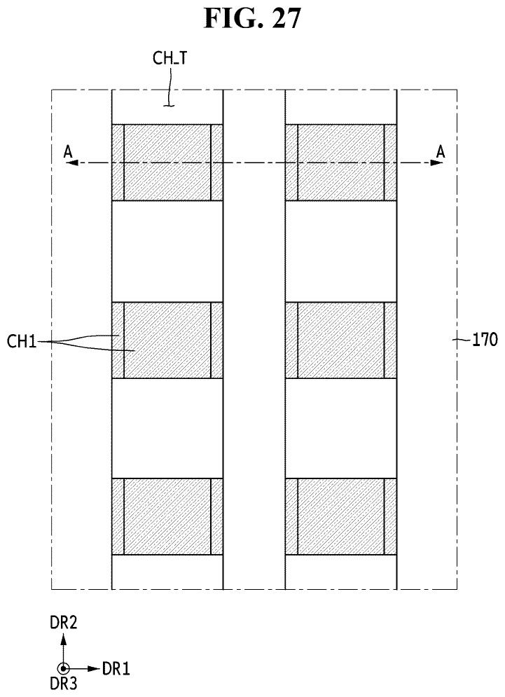

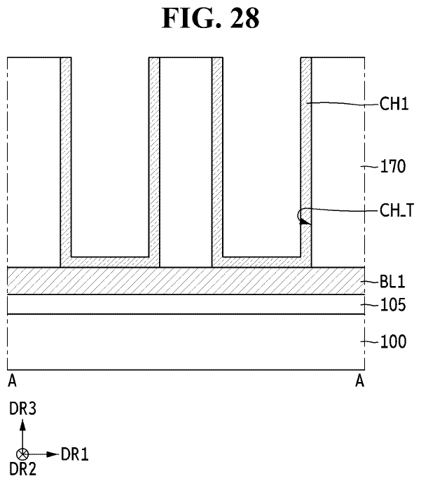

The fabricating process described using FIGS. 25 and 26 may be selectively applied. Therefore, according to one or more example embodiments the fabricating process described using FIGS. 27 and 28 may be performed without the fabricating process described using FIGS. 25 and 26.

Referring to one or more example embodiments shown in FIGS. 27 and 28, the pre-channel pattern CH1_P formed on the upper side of the first protruding insulating pattern 170 may be removed to form the first channel pattern CH1.

The first channel pattern CH1 may be formed along the side wall and bottom side of the first channel trench CH_T. The first channel pattern CH1 may be in contact with the first bit line BL1 exposed by the first channel trench CH_T.

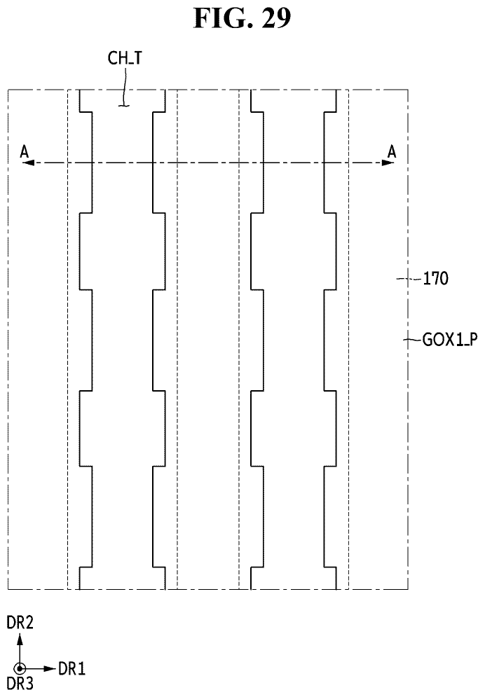

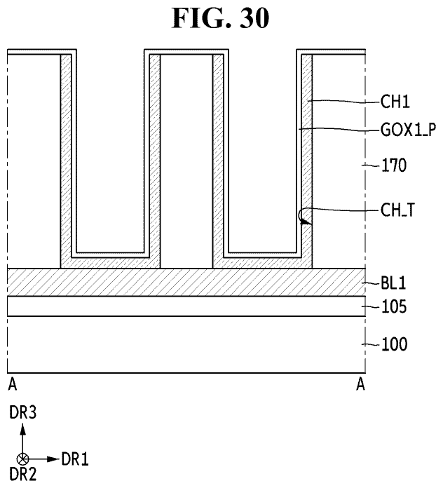

Referring to one or more example embodiments shown in FIGS. 29 and 30, the pre-gate insulating pattern GOX1_P may be formed on the first channel pattern CH1.

The pre-gate insulating pattern GOX1_P may be formed along the profile of the first channel pattern CH1. The pre-gate insulating pattern GOX1_P may be formed on an upper side of the first protruding insulating pattern 170.

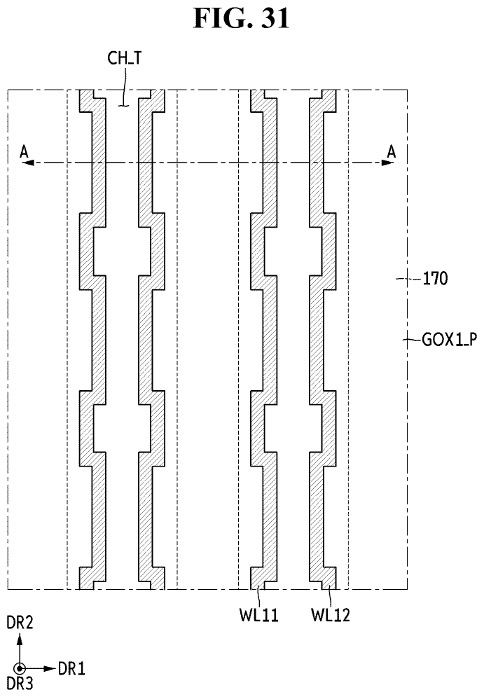

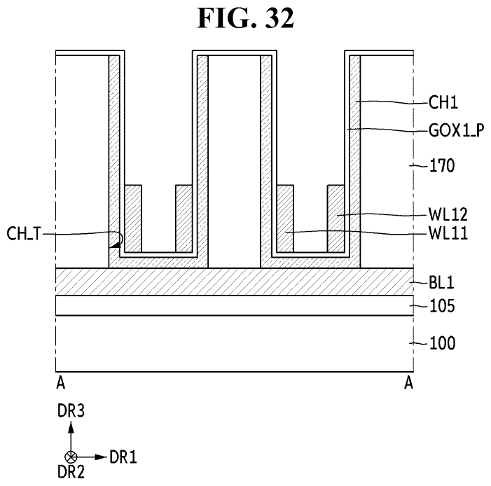

Referring to one or more example embodiments shown in FIGS. 31 and 32, the first word lines WL11 and WL12 may be formed on the pre-gate insulating pattern GOX1_P.

More specifically, a first word line film may be formed on the pre-gate insulating pattern GOX1_P. The first word line film may be anisotropically etched to remove a part of the first word line film. As a result, the first word lines WL11 and WL12 may be formed along the side wall of the first channel trench CH_T.

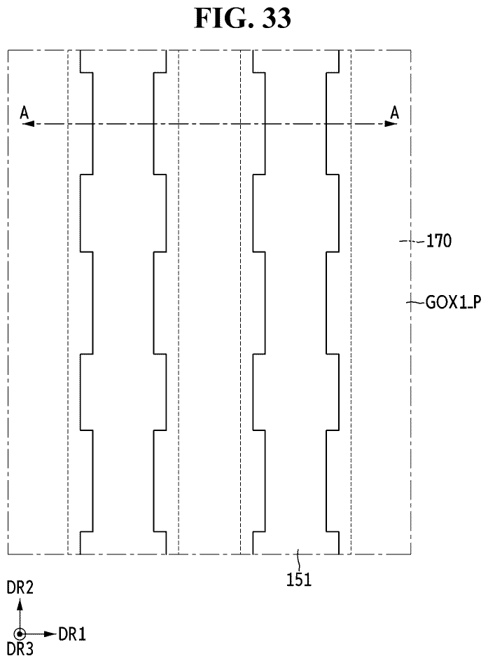

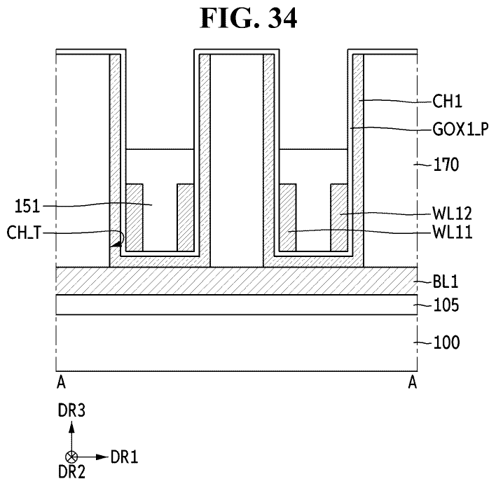

Referring to one or more example embodiments shown in FIGS. 33 and 34, a first isolation insulating pattern 151 may be formed on the first word lines WL11 and WL12.

The first isolation insulating pattern 151 may cover the first word lines WL11 and WL12. The first isolation insulating pattern 151 may fill a part of the first channel trench CH_T.

Because the first isolation insulating pattern 151 fills a part of the first channel trench CH_T, a part of the pre-gate insulating pattern GOX1_P may be exposed.

Referring to one or more example embodiments shown in FIGS. 33, 34, 35 and 36, the pre-gate insulating pattern GOX1_P exposed by the first isolation insulating pattern 151 may be removed.

Accordingly, the first lower gate insulating pattern GOX1 may be formed. The pre-gate insulating pattern GOX1_P formed on the upper side of the first protruding insulating pattern 170 and the pre-gate insulating pattern GOX1_P formed on a part of the side wall of the first channel trench CH_T may be removed, and the first lower gate insulating pattern GOX1 may be formed.

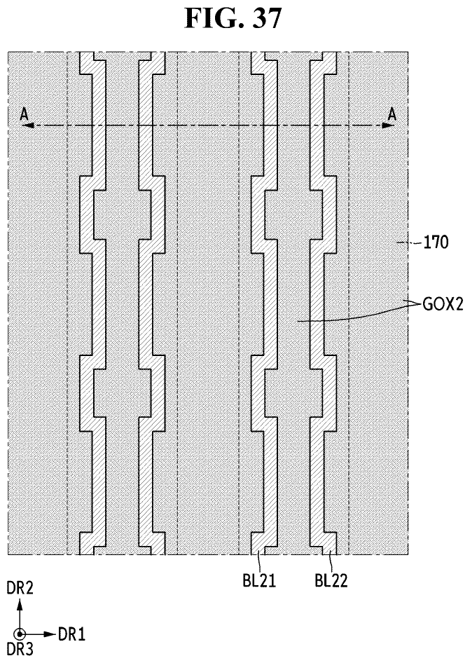

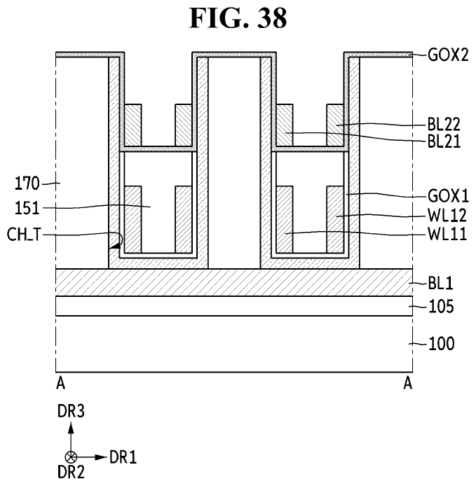

Referring to one or more example embodiments shown in FIGS. 37 and 38, the first upper gate insulating pattern GOX2 may be formed on the first channel pattern CH1 and the first isolation insulating pattern 151.

The first upper gate insulating pattern GOX2 may be formed along the side wall of the first channel trench CH_T and the upper side of the first isolation insulating pattern 151. The first upper gate insulating pattern GOX2 may be formed along the upper side of the first protruding insulating pattern 170. The first upper gate insulating pattern GOX2 may be formed along the profile of the first channel pattern CH1 protruding beyond the upper side of the first isolation insulating pattern 151.

Next, the second bit lines BL21 and BL22 may be formed on the first upper gate insulating pattern GOX2. More specifically, a bit line film may be formed on the first upper gate insulating pattern GOX2. The bit line film may be anisotropically etched to remove a part of the bit line film. Accordingly, the second bit lines BL21 and BL22 may be formed along the side wall of the first channel trench CH_T.

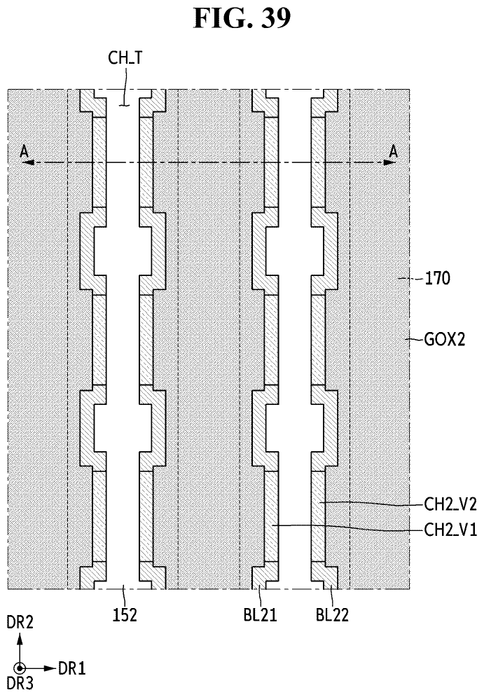

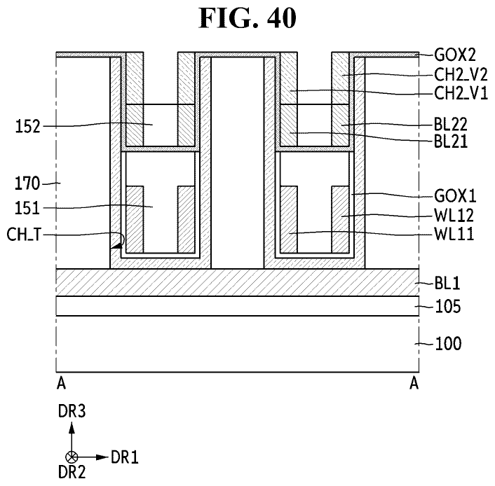

Referring to one or more example embodiments shown in FIGS. 39 and 40, the second isolation insulating pattern 152 may be formed on the first upper gate insulating pattern GOX2.

The second isolation insulating pattern 152 may be formed inside the first channel trench CH_T. The second isolation insulating pattern 152 may be formed between the second bit lines BL21 and BL22 adjacent to each other in the first direction DR1. The second isolation insulating pattern 152 may not cover the upper sides of the second bit lines BL21 and BL22.

Next, the vertical portions CH2_V1 and CH2_V2 of the second channel pattern CH2 may be formed on the second bit lines BL21 and BL22.

More specifically, the first pre-channel film may be formed on the second bit lines BL21 and BL22 and the second isolation insulating pattern 152. The first pre-channel film may be formed along a part of the side wall of the first channel trench CH_T and the upper side of the first protruding insulating pattern 170. Next, the first pre-channel film may be patterned to form a first pre-channel pattern such as the pre-channel pattern CH1_P. From the viewpoint of a plan view, the first pre-channel pattern may have a line pattern shape extending in the first direction DR1. The first pre-channel pattern may be anisotropically etched to remove the first pre-channel pattern on the upper side of the third isolation insulating pattern 153 and the upper side of the first protruding insulating pattern 170. As a result, the vertical portions CH2_V1 and CH2_V2 of the second channel pattern CH2 spaced apart in the first direction DR1 may be formed inside the first channel trench CH_T.

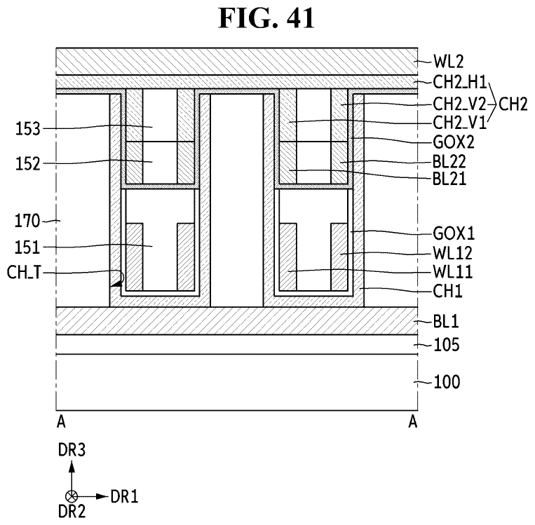

Referring to one or more example embodiments shown in FIG. 41, the third isolation insulating pattern 153 may be formed on the second isolation insulating pattern 152.

The third isolation insulating pattern 153 may be formed between the vertical portions CH2_V1 and CH2_V2 of the second channel pattern CH2 that are adjacent to each other in the first direction DR1. The third isolation insulating pattern 153 may not cover the upper sides of the vertical portions CH2_V1 and CH2_V2 of the second channel pattern CH2.

Subsequently, the horizontal portion CH2_H of the second channel pattern CH2 may be formed on the third isolation insulating pattern 153 and the vertical portions CH2_V1 and CH2_V2 of the second channel pattern CH2. The second word line WL2 may be formed on the horizontal portion CH2_H of the second channel pattern CH2.

Unlike the description of one or more example embodiments using FIGS. 39, 40 and 41, as an example, a first pre-channel pattern having a shape like a pre-channel pattern (CH1_P of FIGS. 23 and 24) may be a part of the second channel pattern CH2. In such a case, the second channel pattern CH2 may have the same shape as that described in FIG. 11.

Unlike the description of one or more example embodiments using FIGS. 39, 40 and 41, as an example, a first pre-channel pattern having a shape like the pre-channel pattern (CH1_P of FIGS. 23 and 24) may be the second channel pattern CH2. In such a case, the second channel pattern CH2 may have the same shape as that described in FIG. 12.

In some embodiments, a method for fabricating a semiconductor device including forming a first bit line extending in a first direction; forming a protruding insulating pattern including a channel trench extending in a second direction, on the first bit line; forming a first channel pattern extending along side walls and along a bottom side of the channel trench; forming a pre-gate insulating pattern along a profile of the first channel pattern and an upper side of the protruding insulating pattern; forming a first word line extending in the second direction, on the pre-gate insulating pattern; forming an isolation insulating pattern that covers the first word line and exposes a part of a pre-gate insulating pattern disposed on the side walls of the channel trench; removing the pre-lower gate insulating pattern exposed by the isolation insulating pattern to form a lower gate insulating pattern; after forming the lower gate insulating pattern, forming an upper gate insulating pattern extending along an upper side of the protruding insulating pattern, the side walls of the channel trench and an upper side of the isolation insulating pattern, the upper gate insulating pattern including a ferroelectric material film; forming a second bit line extending in the second direction on the upper gate insulating pattern, inside the channel trench; forming a second channel pattern on the second bit line; and forming a second word line on the second channel pattern.

Although one or more example embodiments have been particularly shown and above, one or more example embodiments are not limited to the above examples, but may be implemented in various different forms. It will be apparent to those skilled in the art that various changes in form and details may be made therein without departing from the spirit and scope of the following claims.

What is claimed is:

1. A semiconductor device comprising:
a first bit line extending in a first direction, and comprising a first side and a second side opposite to the first side;
a first channel pattern on the first side of the first bit line, and connected to the first bit line;
a first word line on the first channel pattern, and extending in a second direction;
a lower gate insulating pattern between the first channel pattern and the first word line;
a second bit line extending in the second direction, and spaced apart from the first word line in a third direction;
a second channel pattern on the second bit line, and in contact with the second bit line;
an upper gate insulating pattern between the first channel pattern and the second channel pattern, between the first channel pattern and the second bit line, and in contact with the first channel pattern, the upper gate insulating pattern comprising a ferroelectric material film; and
a second word line on the second channel pattern, and extending in the first direction.

2. The semiconductor device of claim 1, wherein the upper gate insulating pattern is in contact with the lower gate insulating pattern.

3. The semiconductor device of claim 1, wherein the first channel pattern comprises a horizontal portion extending in the first direction, and a vertical portion extending in the third direction, and
wherein the first side of the first bit line is connected to the horizontal portion of the first channel pattern.

4. The semiconductor device of claim 3, wherein the vertical portion of the first channel pattern comprises a first side wall and a second side wall opposite to the first side wall,
wherein the first side wall and the second side wall are spaced apart in the first direction, and
wherein the first word line and the second bit line are provided on the first side wall of the vertical portion of the first channel pattern.

5. The semiconductor device of claim 3, wherein the upper gate insulating pattern is in contact with the vertical portion of the first channel pattern.

6. The semiconductor device of claim 1, wherein the second channel pattern comprises a horizontal portion extending in the first direction, and a vertical portion extending in the third direction, and
wherein the vertical portion of the second channel pattern overlaps the first channel pattern in the first direction.

7. The semiconductor device of claim 6, wherein the horizontal portion of the second channel pattern is spaced apart from the first channel pattern in the third direction, and is in contact with the second word line.

8. The semiconductor device of claim 1, wherein each of the first channel pattern and the second channel pattern comprises a metal oxide semiconductor.

9. The semiconductor device of claim 1, wherein the first channel pattern comprises a metal oxide semiconductor, and
wherein the second channel pattern comprises polycrystalline silicon.

10. A semiconductor device comprising:
a first bit line extending in a first direction, and comprising a first side and a second side opposite to the first side;
a first channel pattern on the first side of the first bit line, and which is connected to the first bit line;
a first word line on the first channel pattern, and extending in a second direction;
a lower gate insulating pattern between the first channel pattern and the first word line;
an upper gate insulating pattern on the first word line and the lower gate insulating pattern, and comprising a ferroelectric material film;
a second bit line on the upper gate insulating pattern, and extending in the second direction;
a second channel pattern on the second bit line, and in contact with the second bit line; and
a second word line on the second channel pattern, and extending in the first direction,
wherein the upper gate insulating pattern comprises a horizontal portion extending in the first direction, and vertical portions extending in a third direction, and
wherein the horizontal portion of the upper gate insulating pattern is between the first word line and the second bit line.

11. The semiconductor device of claim 10, wherein the upper gate insulating pattern is in contact with the first channel pattern.

12. The semiconductor device of claim 11, wherein the horizontal portion of the upper gate insulating pattern is in contact with the lower gate insulating pattern.

13. The semiconductor device of claim 10, wherein the second bit line is between the vertical portions of the upper gate insulating pattern, and
wherein the vertical portions of the upper gate insulating pattern are adjacent to each other in the first direction.

14. The semiconductor device of claim 10, wherein the first channel pattern comprises a horizontal portion extending in the first direction, and vertical portions extending in the third direction, and
wherein the first side of the first bit line is connected to the horizontal portion of the first channel pattern.

15. The semiconductor device of claim 14, wherein the vertical portions of the upper gate insulating pattern are between the vertical portions of the first channel pattern, and
wherein the vertical portions of the upper gate insulating pattern are adjacent to each other in the first direction.

16. The semiconductor device of claim 14, wherein the upper gate insulating pattern is in contact with the vertical portions of the first channel pattern.

17. The semiconductor device of claim 10, wherein the second channel pattern comprises a horizontal portion extending in the first direction, and a plurality of vertical portions extending in the third direction, and
wherein each of the vertical portions of the second channel pattern protrudes from the horizontal portion of the second channel pattern toward the first bit line.

18. A semiconductor device comprising:
a first bit line extending in a first direction, and comprising a first side and a second side opposite to the first side;
a protruding insulating pattern on the first side of the first bit line, and comprising a channel trench extending in a second direction;
a first channel pattern extending along side walls and a bottom side of the channel trench, and is connected to the first bit line;
a first lower word line on the first channel pattern and extending in the second direction;
a second lower word line on the first channel pattern, extending in the second direction, and spaced apart from the first lower word line in the first direction;
a lower gate insulating pattern between the first channel pattern and the first lower word line, and between the first channel pattern and the second lower word line;
an upper gate insulating pattern on the first channel pattern, the first lower word line, and the second lower word line, and in contact with the first channel pattern, the upper gate insulating pattern comprising a horizontal portion extending in the first direction, and vertical portions extending in a third direction;
a first upper bit line on the upper gate insulating pattern, and extending in the second direction;
a second upper bit line extending in the second direction, and spaced apart from the first upper bit line in the first direction;
a second channel pattern on the first upper bit line and the second upper bit line, and in contact with the first upper bit line and the second upper bit line; and
a second word line on an upper side of the protruding insulating pattern, and extending in the first direction,
wherein the upper gate insulating pattern comprises a ferroelectric material film.

19. The semiconductor device of claim 18, wherein the horizontal portion of the upper gate insulating pattern is in contact with the lower gate insulating pattern.

20. The semiconductor device of claim 18, wherein the upper gate insulating pattern extends along the upper side of the protruding insulating pattern.
